(19) United States
(12) Patent Application Publication
(10) Pub. No.: US 2026/0076012 A1
(43) Pub. Date: Mar. 12, 2026

(54) DISPLAY PANEL AND DISPLAY DEVICE

(71) Applicant: Tianma Advanced Display Technology Institute (Xiamen) Co., Ltd., Xiamen (CN)

(72) Inventor: Zaiwang Liu, Xiamen (CN)

(73) Assignee: Tianma Advanced Display Technology Institute (Xiamen) Co., Ltd., Xiamen (CN)

(21) Appl. No.: 19/394,957

(22) Filed: Nov. 20, 2025

(30) Foreign Application Priority Data
Jun. 30, 2025 (CN) 202510897458.X

(51) Int. Cl. H10H 29/855

(52) U.S. Cl. CPC H10H 29/8552

(57) ABSTRACT

Provided are a display panel and a display device. The display panel includes a base substrate, an insulating layer located on one side of the base substrate in a thickness direction, where the surface of one side of the insulating layer facing away from the base substrate is provided with a groove structure, a light-shielding layer and a light-emitting element that are located on the side of the insulating layer facing away from the base substrate, where the orthographic projection of the light-shielding layer on the base substrate is at least located around the orthographic projection of the light-emitting element on the base substrate, and at least part of the light-shielding layer is located within the groove structure. As such, the groove structure is formed so that a light-shielding material can be accommodated within the groove structure during inkjet printing.

### CROSS-REFERENCE TO RELATED APPLICATION

The present application claims priority to Chinese Patent Application No. 202510897458.X, filed with the China National Intellectual Property Administration (CNIPA) on Jun. 30, 2025, the disclosure of which is incorporated herein by reference in its entirety.

### TECHNICAL FIELD

Embodiments of the present disclosure relate to the technical field of display panels and, in particular, to a display panel and a display device.

### BACKGROUND

With the development of display technology, display panels, as the core of display devices, have become increasingly popular among users. To meet user demands, micro light-emitting diode (microLED) display panels have been developed.

For existing microLED display panels, the light-emitting efficiency of light-emitting elements is relatively low, which affects the display performance of the display panels. Therefore, how to improve the display performance, such as the display effect, of a microLED display panel has become a focus of attention.

### SUMMARY

The present disclosure provides a display panel and a display device. An insulating layer is provided with a groove structure, and at least part of a light-shielding layer is located within the groove structure so that the light-shielding layer can be accommodated within the groove structure during inkjet printing, thereby preventing the light-shielding layer from prematurely contacting a light-emitting element, lowering the probability of the light-shielding layer creeping onto the light-emitting element, preventing the light-shielding layer from blocking the light-emitting element, improving the light-emitting efficiency of the light-emitting element, and enhancing the display effect of the display panel.

In a first aspect, the present disclosure provides a display panel. The display panel includes a base substrate, an insulating layer, a light-shielding layer, and a light-emitting element.

The insulating layer is located on one side of the base substrate in a thickness direction, and a surface of one side of the insulating layer facing away from the base substrate is provided with groove structures.

The light-shielding layer and the light-emitting element are located on the side of the insulating layer facing away from the base substrate, an orthographic projection of the light-shielding layer on the base substrate is at least located around an orthographic projection of the light-emitting element on the base substrate, and at least part of the light-shielding layer is located within the groove structures.

In a second aspect, the present disclosure further provides a display device including the preceding display panel.

In the technical solutions of the present disclosure, the surface of the side of the insulating layer facing away from the base substrate is provided with the groove structures, and at least part of the light-shielding layer is located within the groove structures. Essentially, when the light-shielding layer is formed by inkjet printing using a semi-fluid light-shielding material, the presence of the groove structure on the surface of the insulating layer causes the light-shielding layer to preferentially fill the groove structure as the light-shielding layer flows over the surface of the insulating layer. Only after the groove structure is filled is the light-shielding layer deposited on the surface of the side of the insulating layer facing away from the base substrate. This prevents the light-shielding layer from creeping onto the outer side of the light-emitting element, thereby ensuring the light-emitting efficiency of the light-emitting element. Embodiments of the present disclosure address the existing problem that when the light-shielding layer is directly formed on the surface of the insulating layer, the semi-fluid light-shielding layer tends to creep up to the outer side of the light-emitting element, reducing the light-emitting efficiency of the light-emitting element. This can prevent the light-shielding layer from self-leveling and effectively lower the fluid level of the light-shielding layer around the light-emitting element. This creates a fluid level difference between a region near the light-emitting element and a region away from the light-emitting element, increasing the difficulty of the light-shielding layer creeping onto the sidewall of the light-emitting element. As a result, the probability of the light-shielding layer creeping onto the sidewall of the light-emitting element due to the capillary effect caused by a microstructure on the upper surface of the light-emitting element is lowered. Consequently, this prevents light emission from the sidewall of the light-emitting element from being blocked by the light-shielding layer, ensuring the light-emitting efficiency on the sidewall of the light-emitting element and enhancing the display effect of the display panel.

### BRIEF DESCRIPTION OF DRAWINGS

FIG. 1 is a diagram illustrating the structure of a display panel according to embodiments of the present disclosure.

FIG. 2 is a top view of a display panel according to embodiments of the present disclosure.

FIG. 3 is a top view of a display panel without a light-emitting element bonded according to embodiments of the present disclosure.

FIG. 4 is a top view of a display panel with light-emitting elements bonded according to embodiments of the present disclosure.

FIG. 5 is a cross-sectional view of the display panel corresponding to FIG. 4.

FIG. 6 is another top view of a display panel according to embodiments of the present disclosure.

FIG. 7 is a cross-sectional view of the display panel corresponding to FIG. 6.

FIG. 8 is another top view of a display panel according to embodiments of the present disclosure.

FIG. 9 is another top view of a display panel according to embodiments of the present disclosure.

FIG. 10 is another top view of a display panel according to embodiments of the present disclosure.

FIG. 11 is another top view of a display panel according to embodiments of the present disclosure.

FIG. 12 is a first diagram of the arrangement of blind holes according to embodiments of the present disclosure.

FIG. 13 is a second diagram of the arrangement of blind holes according to embodiments of the present disclosure.

FIG. 14 is a diagram illustrating the structure in which the depth of a first blind hole is smaller than the depth of a second blind hole according to embodiments of the present disclosure.

FIG. 15 is a diagram illustrating the structure in which the depth of a first blind hole is larger than the depth of a second blind hole according to embodiments of the present disclosure.

FIG. 16 is another top view of a display panel according to embodiments of the present disclosure.

FIG. 17 is another top view of a display panel according to embodiments of the present disclosure.

FIG. 18 is a cross-sectional view of the display panel shown in FIG. 16 or FIG. 17.

FIG. 19 is another top view of a display panel according to embodiments of the present disclosure.

FIG. 20 is a cross-sectional view of the display panel shown in FIG. 19.

FIG. 21 is another diagram illustrating the structure of a display panel according to embodiments of the present disclosure.

FIG. 22 is another diagram illustrating the structure of a display panel according to embodiments of the present disclosure.

FIG. 23 is a diagram illustrating the structure of a display device according to embodiments of the present disclosure.

### DETAILED DESCRIPTION

The present disclosure is further described in detail below in conjunction with the drawings and embodiments. It is to be understood that the embodiments described herein are intended to illustrate the present disclosure and not to limit the present disclosure. Additionally, it is to be noted that for ease of description, only part, not all, of structures related to the present disclosure are illustrated in the drawings.

Terms used in the embodiments of the present disclosure are intended only to describe the specific embodiments and not to limit the present disclosure. It is to be noted that nouns of locality such as “on”, “below”, “left”, and “right” in the embodiments of the present disclosure are described from angles shown in the drawings and are not to be construed as limiting the embodiments of the present disclosure. Additionally, in the context, it is to be understood that when an element is formed “on” or “below” another element, the element can not only be directly formed “on” or “below” the other element but also be indirectly formed “on” or “below” the other element via an intermediate element. Terms such as “first” and “second” are used only for the purpose of description to distinguish between different components and not to indicate any order, quantity, or importance. For those of ordinary skill in the art, specific meanings of the preceding terms in the present disclosure may be understood based on specific situations.

The terms “comprise”, “include”, and variations thereof in the present disclosure are intended to be inclusive, that is, “including, but not limited to”. The term “based on” is “at least partially based on”. The term “an embodiment” refers to “at least one embodiment”.

It is to be noted that references to “first”, “second”, and the like in the present disclosure are intended to distinguish corresponding contents and are not intended to limit an order or an interrelationship.

It is to be noted that “one” and “a plurality” mentioned in the present disclosure are illustrative and not limiting, and that those skilled in the art should understand that “one” and “a plurality” should be understood as “one or more” unless otherwise specified.

Before the technical solutions provided in the embodiments of the present disclosure are set forth, to facilitate the understanding of the embodiments of the present disclosure, the present disclosure first specifically describes the problems existing in the related art.

The inventors have found that the spliced display products require light-shielding materials to achieve an integrated black effect. For micro light-emitting diodes (microLEDs), inkjet printing of light-shielding materials is one of the mainstream technical solutions in the industry to enable light shielding. During inkjet printing, a light-shielding material is initially in the form of semi-fluid ink. When the side surface of a micro light-emitting diode chip comes into contact with the ink, a microstructure present on the surface of the micro light-emitting diode chip induces a capillary effect. This capillary effect causes the ink to be drawn up, resulting in the printed ink creeping along the sidewall of the chip in a pixel region and even covering the surface of the chip. Such ink accumulation obstructs light emission from the chip, reduces the light-emitting efficiency and brightness of the chip, and adversely affects the overall display effect of the display panel.

To solve the preceding technical problems, lower the probability of the light-shielding material creeping up to the sidewall of the chip, ensure the light-emitting efficiency of the chip, and enhance the display effect of the display panel, the present disclosure provides the design solution of a corresponding groove structure to prevent a light-shielding layer from creeping up to the sidewall of a light-emitting element. Specifically, embodiments of the present disclosure provide a display panel.

The display panel includes a base substrate, an insulating layer, a light-shielding layer, and a light-emitting element.

The insulating layer is located on one side of the base substrate in a thickness direction, and the surface of one side of the insulating layer facing away from the base substrate is provided with a groove structure.

The light-shielding layer and the light-emitting element are located on the side of the insulating layer facing away from the base substrate, the orthographic projection of the light-shielding layer on the base substrate is at least located around the orthographic projection of the light-emitting element on the base substrate, and at least part of the light-shielding layer is located within the groove structure.

In the preceding technical solutions, the surface of the side of the insulating layer facing away from the base substrate is provided with the groove structure, and at least part of the light-shielding layer is located within the groove structure. Essentially, when the light-shielding layer is formed by inkjet printing using a semi-fluid light-shielding material, the presence of the groove structure on the surface of the insulating layer causes the light-shielding layer to preferentially fill the groove structure as the light-shielding layer flows over the surface of the insulating layer. Only after the groove structure is filled is the light-shielding layer deposited on the surface of the side of the insulating layer facing away from the base substrate. Part of the light-shielding layer is accommodated within the groove structure so that the light-shielding layer is prevented from creeping up to the outer side of the light-emitting element, thereby ensuring the light-emitting efficiency of the light-emitting element. The embodiments of the present disclosure address the existing problem that when the light-shielding layer is directly formed on the surface of the insulating layer, the semi-fluid light-shielding layer tends to creep up to the outer side of the light-emitting element, reducing the light-emitting efficiency of the light-emitting element. This can prevent the light-shielding layer from self-leveling and effectively lower the fluid level of the light-shielding layer around the light-emitting element. This creates a fluid level difference between a region near the light-emitting element and a region away from the light-emitting element, increasing the difficulty of the light-shielding layer creeping onto the sidewall of the light-emitting element. As a result, the probability of the light-shielding layer creeping onto the sidewall of the light-emitting element due to the capillary effect caused by a microstructure on the upper surface of the light-emitting element is lowered. Consequently, this prevents light emission from the sidewall of the light-emitting element from being blocked by the light-shielding layer, ensuring the light-emitting efficiency on the sidewall of the light-emitting element and enhancing the display effect of the display panel.

The preceding is the core idea of the present disclosure. The technical solutions in the embodiments of the present disclosure are described clearly and completely hereinafter in conjunction with the drawings in the embodiments of the present disclosure. Based on the embodiments of the present disclosure, all other embodiments obtained by those of ordinary skill in the art without any creative efforts are within the scope of the present disclosure.

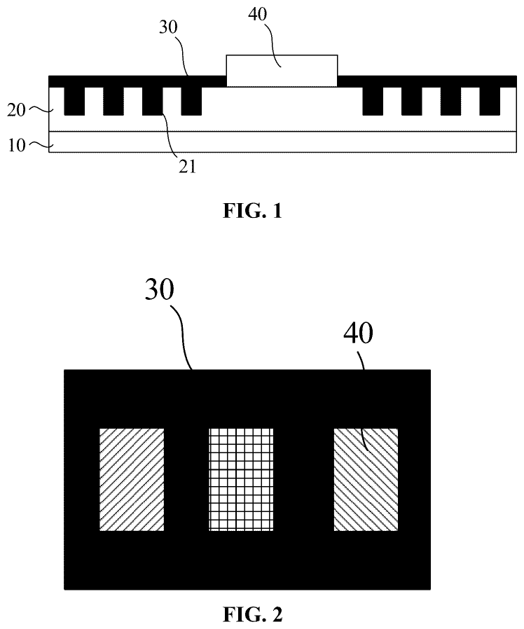

FIG. 1 is a diagram illustrating the structure of a display panel according to embodiments of the present disclosure. FIG. 2 is a top view of a display panel according to embodiments of the present disclosure. Referring to FIGS. 1 and 2, the display panel includes a base substrate 10, an insulating layer 20 located on one side of the base substrate 10 in a thickness direction, where the surface of one side of the insulating layer facing away from the base substrate is provided with groove structures 21, a light-shielding layer 30 and light-emitting elements 40 that are located on the side of the insulating layer 20 facing away from the base substrate 10, where the orthographic projection of the light-shielding layer 30 on the base substrate 10 is at least located around the orthographic projection of a light-emitting element 40 on the base substrate 10, and at least part of the light-shielding layer 30 are located within the groove structures 21 respectively.

As the support structure of the display panel, the base substrate 10 is configured to provide physical support for other structural layers on the display panel, thereby ensuring the stability of the display panel. In this embodiment, the base substrate 10 may be a flexible substrate. The material of the base substrate 10 may include one or more polymer resins selected from polyethersulfone, polyacrylate, polyetherimide, polyethylene naphthalate, polyethylene terephthalate, polyphenylene sulfide, polyarylate, polyimide, polycarbonate, and cellulose acetate propionate. The base substrate 10 may also be a rigid substrate, such as a glass substrate or another type of rigid substrate. The material of the base substrate 10 is not specifically limited in the embodiments of the present disclosure. The insulating layer 20 is a material layer used to improve the surface flatness of the display panel and may typically include materials such as a transparent resin. The material of the insulating layer 20 may include one or more organic materials of polyimide, polyethylene terephthalate, polycarbonate, polyethylene, or polyacrylate, which is not limited herein. In this embodiment, the surface of the insulating layer 20 is provided with the groove structures 21 to respectively accommodate the parts of the light-shielding layer 30. The groove structures 21 may include, but are not limited to, blind holes. The shape of a groove structure 21 may include, but is not limited to, at least one of an annular groove, a rectangle, a circle, and a square, which may be determined based on actual conditions and is not limited herein. As a component in the display panel responsible for emitting light, the light-emitting element 40 enables a display region of the display panel to present a corresponding image. Driven by an external voltage, electrons and holes in the light-emitting element 40 recombine to form excitons. The excitons emit photons when de-exciting, thereby generating visible light and fulfilling the display function. In this embodiment, the light-emitting element 40 may include a light-emitting diode or a micro light-emitting diode, which is not limited herein. Moreover, the light-emitting elements 40 may include a red light-emitting element, a green light-emitting element, a blue light-emitting element, and a white light-emitting element, which is not limited herein. The light-shielding layer 30 is configured to present an integrated black effect on the display panel when the light-emitting element 40 is not emitting light, thereby improving the appearance of the display panel. During the preparation process, the light-shielding layer 30 is formed by applying a semi-fluid and viscous black light-shielding material to a non-light-emitting element region of the display panel using a process such as inkjet printing and then curing. This black light-shielding material may include, but is not limited to, ink.

Specifically, the insulating layer 20 is provided on the side of the base substrate 10, the side of the insulating layer 20 facing away from the base substrate 10 is provided with the groove structures 21, and the at least part of the light-shielding layer 30 are located within the groove structures 21 respectively. That is to say, the groove structures 21 provided on the surface of the side of the insulating layer 20 facing away from the base substrate 10 can be configured to accommodate parts of the light-shielding layer 30 respectively. In other words, the parts of the light-shielding layer 30 fill the groove structures 21 during inkjet printing, and only after the groove structures 21 are filled with the light-shielding layer 30 is the remaining part of the light-shielding layer 30 deposited on the surface of the side of the insulating layer 20 facing away from the base substrate 10. The advantage of such a configuration is that when the light-shielding layer 30 is formed on the side of the insulating layer 20 by inkjet printing, the semi-fluid light-shielding layer 30 preferentially fills the groove structures 21 on the insulating layer 20, and only after the groove structures 21 are filled is the remaining light-shielding layer 30 deposited on the surface of the insulating layer 20, thereby lowering the fluid level of the light-shielding layer 30 around the periphery of the light-emitting element 40, lowering the probability of the light-shielding layer 30 creeping onto the sidewall of the light-emitting element 40 due to the capillary effect caused by the microstructure on the sidewall of the light-emitting element 40, and ensuring the light-emitting efficiency of the light-emitting element 40.

Additionally, the light-shielding layer 30 and the light-emitting element 40 are located on the side of the insulating layer 20 facing away from the base substrate 10. Referring to FIG. 2, the light-shielding layer 30 is located in a peripheral region of the light-emitting element 40, that is, the light-emitting element 40 is located in the middle of the light-shielding layer 30, and the orthographic projection of the light-shielding layer 30 on the base substrate 10 is at least located around the orthographic projection of the light-emitting element 40 on the base substrate 10. In other words, from a top view, the light-emitting element 40 is located in a region encircled by the light-shielding layer 30, that is, part of the light-shielding layer 30 surrounds the peripheral region of the light-emitting element 40. Additionally, the light-shielding layer 30 may also be located in a region between the light-emitting element 40 and the insulating layer 20 and overlapping the light-emitting element 40, or may also be located in a region between adjacent light-emitting elements 40 to ensure an integrated black effect when the light-emitting elements 40 are not emitting light, thereby enhancing the user experience.

Moreover, since the groove structures 21 accommodate the parts of the semi-fluid light-shielding layer 30 respectively, and the orthographic projection of the light-shielding layer 30 on the base substrate 10 is at least located around the orthographic projection of the light-emitting element 40 on the base substrate 10, that is, the light-shielding layer 30 surrounds the light-emitting element 40, the light-shielding layer 30 located around the light-emitting element 40 does not come into contact with the light-emitting element 40 prematurely after the light-shielding layer 30 fills the groove structures 21. As a result, the probability of the light-shielding layer 30 creeping onto the sidewall of the light-emitting element 40 due to the capillary effect caused by the microstructure on the upper surface of the light-emitting element 40 is lowered. Consequently, the light emission from the sidewall of the light-emitting element 40 is not blocked, thereby ensuring the light-emitting efficiency on the sidewall of the light-emitting element 40 and ultimately enhancing the display effect of the display panel. Additionally, filling the light-shielding layer 30 into the groove structures 21 can prevent the light-shielding layer 30 from self-leveling and effectively lower the fluid level around the light-emitting element 40 so that the fluid level difference is formed between the region near the light-emitting element 40 and the region away from the light-emitting element 40, thereby increasing the difficulty of the light-shielding layer 30 creeping onto the sidewall of the light-emitting element 40 and ensuring the light-emitting efficiency on the sidewall of the light-emitting element 40.

It is to be noted that the film structure of the display panel shown in FIG. 1 does not represent the entirety of the film structure of the display panel, but represents only part of the film structure of the display panel. In addition to the main films illustrated in FIG. 1, the display panel may further include other films, which is not specifically limited in the embodiments of the present disclosure. Moreover, the relative positional relationship between the films shown in FIG. 1 is an exemplary positional relationship of the embodiments of the present disclosure. Under the premise that the core invention of the embodiments of the present disclosure can be achieved, those skilled in the art may make various modifications based on the film relationship, which is not specifically limited in the embodiments of the present disclosure.

It is to be understood that the display panel may further include the display region and a non-display region. The groove structures 21 mentioned in this embodiment may be located in the display region, in the non-display region, or partly in the display region and partly in the non-display region. On the premise that the at least part of the light-shielding layer 30 can be located in the groove structures 21 respectively, the specific positions of the groove structures 21 are not limited in the embodiments of the present disclosure.

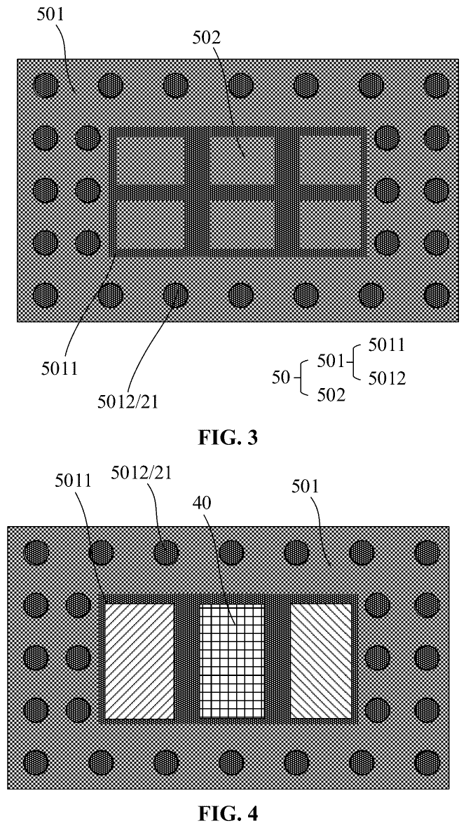

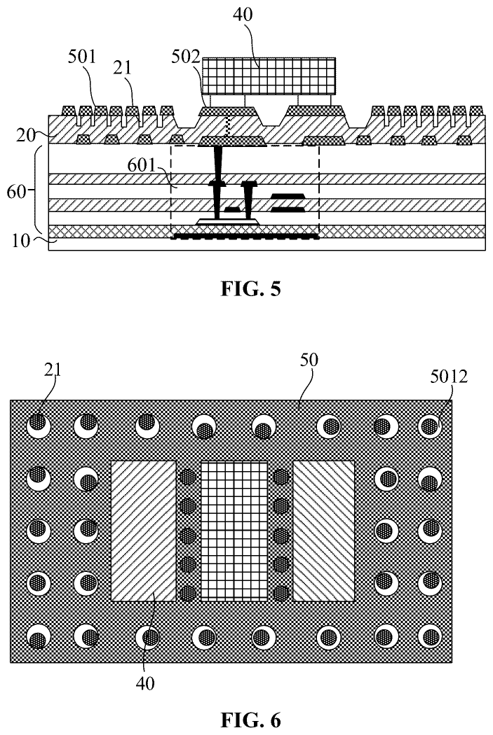

In one or more embodiments, FIG. 3 is a top view of a display panel without a light-emitting element bonded according to embodiments of the present disclosure, FIG. 4 is a top view of a display panel with light-emitting elements bonded according to embodiments of the present disclosure, and FIG. 5 is a cross-sectional view of the display panel corresponding to FIG. 4. Referring to FIGS. 3 to 5, the display panel further includes a metal layer 50 located between the insulating layer 20 and the light-shielding layer 30; the metal layer 50 includes a first metal portion 501, and the first metal portion 501 has a first opening 5011 and second openings 5012; the orthographic projection of the light-emitting element 40 on the base substrate 10 is located in the orthographic projection of the first opening 5011 on the base substrate 10, and the orthographic projections of the second openings 5012 on the base substrate 10 at least partially overlap the orthographic projections of the groove structures 21 on the base substrate 10 respectively.

The metal layer 50 is configured to enable the light-emitting element 40 to emit light. In this embodiment, the metal layer 50 includes the first metal portion 501, and the first metal portion 501 includes the first opening 5011 and the second openings 5012. The light-emitting element 40 is disposed within the first opening 5011. The second openings 5012 are located in a peripheral region of the first opening 5011 and are configured to expose the groove structures 21 respectively to ensure that the light-shielding layer 30 fills the groove structures 21.

Specifically, the orthographic projection of the light-emitting element 40 on the base substrate 10 is located in the orthographic projection of the first opening 5011 on the base substrate 10. That is, a projection region of the first opening 5011 is larger than a projection region of the light-emitting element 40. From a top view, the light-emitting element 40 is located within the first opening 5011. As such, as shown in FIG. 4, when the light-emitting element 40 is disposed, it can be ensured that the light-emitting element 40 is located within the first opening 5011, without affecting the light-emitting effect of the light-emitting element 5011.

It is also to be noted that the orthographic projections of the second openings 5012 on the base substrate 10 at least partially overlap the orthographic projections of the groove structures 21 on the base substrate 10 respectively, that is, a projection region of a second opening 5012 is greater than or equal to a projection region of a groove structure 21. In other words, the projection region of the second opening 5012 can completely overlap the projection region of the groove structure 21 or can surround the projection region of the groove structure 21 so that the projection region of the groove structure 21 is located within the projection region of the second opening 5012. Alternatively, the projection region of the second opening 5012 can partially overlap the projection region of the groove structure 21, that is, there are common and non-common portions between the projection region of the second opening 5012 and the projection region of the groove structure 21. This ensures that part of the groove structure 21 or the entire groove structure 21 can be exposed at the second opening 5012. When the part of the groove structure 21 is exposed, part of the metal layer 30 is located within the groove structure 21. When the semi-fluid light-shielding layer 30 is formed by inkjet printing, the light-shielding layer 30 can preferentially fill the exposed groove structure 21, and only after the groove structure 21 is filled is the light-shielding layer 30 deposited on the surface of the metal layer 50, thereby lowering the fluid level of the light-shielding layer 30 around the periphery of the light-emitting element 40. As such, the light-shielding layer 30 cannot approach the sidewall of the light-emitting element 40 prematurely, thereby ensuring the light-emitting efficiency of the light-emitting element 40 and enhancing the display effect of the display panel.

Typically, the insulating layer 20 is an organic insulating layer. Compared to the organic insulating layer 20, the surface of the metal layer 50 is typically hydrophobic. The fluidity of the light-shielding layer 30 can be enhanced by disposing the metal layer 50 between the light-shielding layer 30 and the insulating layer 20 and forming the light-shielding layer 30 on the surface of the metal layer 50, thereby improving the self-leveling effect and efficiency of the light-shielding layer 30 on the metal layer 50. This avoids the problem that local regions of the metal layer 50 are not covered with the light-shielding layer 30 or that the semi-fluid light-shielding layer 30 has uneven thickness on the surface of the metal layer 50. The problem can adversely affect the integrated black effect of the display panel and degrade the user experience.

Additionally, it is to be emphasized that, in the solution of the present disclosure, since the groove structures 21 are provided on the insulating layer 20 to accommodate the parts of the light-shielding layer 30 respectively, the probability of the light-shielding layer 30 creeping onto the light-emitting element 40 is lowered. However, this also results in a thickness difference between the light-shielding layer 30 filling regions of the groove structures 21 and the light-shielding layer 30 covering regions without the groove structures 21. Consequently, the thinner regions of the light-shielding layer 30 can exhibit reduced light-shielding effect, and the overall uniformity of the light-shielding effect of the light-shielding layer 30 can deteriorate. In the embodiments of the present disclosure, by utilizing the metal layer used for electrode preparation, the first metal portion 501 covering the insulating layer 20 is formed simultaneously during the electrode preparation process. The metal layer can reduce the light-shielding difference between the light-shielding layer in the non-groove regions and the light-shielding layer in the groove regions, thereby ensuring the integrated black effect of the display panel.

Additionally, during the preparation process, a metal layer 50 may first be formed on the surface of the side of the insulating layer 20 facing away from the base substrate 10 in manners such as deposition or magnetron sputtering. Patterned shapes can be formed on the surface of the metal layer 50 by performing photolithography and development on the first metal portion 501 of the metal layer 50. The patterned shapes are at least the same as the corresponding positions of the groove structures 21. In other words, the second openings 5012 are formed at the corresponding positions of the groove structures 21 around the periphery of the first opening 5011, and the first opening 5011 is formed in the periphery of the position of the light-emitting element 40 located above the metal layer 50. As such, the position of the light-emitting element 40 can be exposed, ensuring that the first opening 5011 does not block the position of the light-emitting element 40 and thus does not affect the light emission of the light-emitting element 40. Moreover, at least parts of the positions of the groove structures 21 can also be exposed, ensuring that the second openings 5012 do not block the positions of the groove structures 21 respectively and thereby allowing the light-shielding layer 30 to fill the groove structures 21. This lowers the fluid level of the light-shielding layer 30 and lowers the probability of the light-shielding layer 30 creeping onto the sidewall of the light-emitting element 40, ensuring the light-emitting efficiency of the light-emitting element 40 and enhancing the display effect of the display panel.

In one or more embodiments, with continued reference to FIGS. 3 to 5, the metal layer 50 further includes second metal portions 502 located within the first opening 5011; the display panel further includes a circuit function layer 60 located between the base substrate 10 and the insulating layer 20. The circuit function layer 60 includes a pixel circuit 601 electrically connected to a second metal portion 502, and the second metal portion 502 is electrically connected to the light-emitting element 40.

The second metal portion 502 is configured to connect the pixel circuit 601 and the light-emitting element 40. Specifically, the second metal portion 502 may be understood as a pixel electrode. The pixel electrode may correspond to M3 and M4 as shown in FIG. 5. That is, the pixel circuit 601 is electrically connected to the light-emitting element 40 via metals M3 and M4 so that the pixel circuit 601 drives the light-emitting element 40 through the second metal portion 502, thereby enabling the light-emitting element 40 to emit light. The circuit function layer 60 is located on the side of the base substrate 10 and is a film configured to fulfill various electrical functions of the display panel. In this embodiment, the circuit function layer 60 includes the pixel circuit 601. The pixel circuit 601 is a basic function unit in the display panel and is responsible for controlling the display state (such as brightness and color) of a single pixel, that is, for driving the light-emitting element 40 to emit light. Typically, the pixel circuit 601 may include structures such as a transistor T. In this case, the pixel circuit 601 should at least include a semiconductor layer, a gate metal layer, a source-drain metal layer, and an insulating interlayer located between every adjacent conductive films. The semiconductor layer includes an active layer of the transistor T, the gate metal layer includes a gate of the transistor T, and the source-drain metal layer includes a source and drain of the transistor T. The pixel circuit 601 may be prepared by deposition, evaporation, coating, inkjet printing, or other manners. The formation manners of various structures may be set based on the actual requirements of a display panel manufacturing method, which is not specifically limited herein. As such, since the formation of structures such as the transistor T in the pixel circuit 601 involves patterning the semiconductor layer, the gate metal layer, and source-drain metal layer, and others, the surface of one side of the circuit function layer 60 facing away from the base substrate 10 presents an uneven structure. Therefore, the circuit function layer 60 may further include a gate insulating layer and a dielectric layer shown in the figure to achieve the flatness of the circuit function layer 60.

The circuit function layer 60 may be prepared by deposition, evaporation, coating, inkjet printing, or other manners. The formation manners of various structures may be set based on the actual requirements of the display panel manufacturing method, which is not specifically limited herein. For the transistor T, the specific materials of the gate, the source, the drain, and the active layer may also be set by those skilled in the art based on the actual conditions, which is not limited herein. Exemplarily, the gate may be made of molybdenum, titanium-aluminum-titanium, or another material; the source and the drain may be made of molybdenum-aluminum-molybdenum, titanium-aluminum-titanium, or another material; the active layer may be made of low-temperature polycrystalline silicon, an oxide semiconductor, or another material.

It is to be noted that the second metal portion 502 is electrically connected to the light-emitting element 40. In other words, the second metal portion 502 is provided with positive and negative electrodes, namely a cathode and an anode. The cathode and the anode are configured to connect a cathode of the light-emitting element 40 and an anode of the light-emitting element 40 respectively, ensuring that the light-emitting element 40 is energized and emits light normally. In some embodiments, in addition to three illustrated light-emitting elements 40 of red, green, and blue, three pairs of redundant electrodes are also provided. The redundant electrodes are configured to maintain normal light emission when the light-emitting elements 40 fail during testing. In other words, the second metal portion 502 includes six pairs of electrodes, where three pairs of electrodes are configured to connect the light-emitting elements 40, and the remaining three pairs of electrodes are connected to backup redundant electrodes, to ensure the light-emitting function of the light-emitting elements 40.

Additionally, as required, the groove structures 21 may also be prepared in the first opening 5011. In other words, after an entire metal layer 50 is formed during the preparation process, photolithography and development are performed on the second metal portions 502 of the metal layer 50 to respectively form patterned shapes on the surfaces of the second metal portions 502. Afterward, the second metal portions 502 forming the patterned shapes are etched using etching and other processes to ultimately form the corresponding groove structures 21 on the insulating layer 20. Referring to FIG. 5, the groove structures 21 are formed in the insulating layer 20 below the light-emitting element 40, which corresponds to the patterned thick line in the longitudinal direction within the first opening 5011 shown in FIG. 4. As such, the second metal portions 502 may be regarded as masks to prepare the groove structures 21, thereby saving process steps.

In one or more embodiments, with continued reference to FIG. 3, the orthographic projections of the second openings 5012 on the base substrate 10 coincide with the orthographic projections of the groove structures 21 on the base substrate 10 respectively. That is, the projection region of the second opening 5012 is the same as the projection region of the groove structure 21, and the projection of the second opening 5012 on the base substrate 10 completely overlaps the projection of the groove structure 21 on the base substrate 10, that is, the groove structure 21 is just completely exposed in this case. The advantage of such a configuration is that the light-shielding layer 30 can preferentially fill the groove structures 21, thereby lowering the probability of the light-shielding layer 30 creeping onto the light-emitting element 40, even preventing the light-shielding layer 30 from creeping onto the light-emitting element 40, preventing the light-shielding layer 30 from blocking the light-emitting element 40, improving the light-emitting efficiency of the light-emitting element 40, and enhancing the display effect of the display panel.

Additionally, during the preparation process, due to the presence of the second openings 5012 on the first metal portion 501, the first metal portion 501 can serve as a mask. The groove structures 21 located on the insulating layer 20 can be ultimately formed on sides of the second openings 5012 facing the base substrate 10 respectively by performing etching and development in the regions of the second openings 5012 of the first metal portion 501. As such, using the first metal portion 501 as the mask can not only save the process steps for preparing the groove structures 21 but also ensure that the groove structures 21 are not prematurely filled. This can allow the groove structures 21 to effectively accommodate the light-shielding layer 30 during the inkjet printing of the light-shielding layer 30, thereby lowering the fluid level of the light-shielding layer 30 around the light-emitting element 40. As a result, this prevents the light-shielding layer 30 from creeping onto the sidewall of the light-emitting element 40 due to the capillary effect caused by the microstructure on the surface of the light-emitting element 40, which could otherwise adversely affect the light-emitting efficiency of the light-emitting element 40 and degrade the display effect of the display panel. Additionally, the parts of the light-shielding layer 30 fill the groove structures 21 respectively so that the thickness of the light-shielding layer 30 in the groove structures 21 is larger than the thickness of the light-shielding layer 30 in the non-groove regions. Moreover, since the surface of the metal layer 50 is hydrophobic, forming the light-shielding layer 30 on the surface of the metal layer 50 helps enhance the fluidity of the light-shielding layer 30, thereby improving the self-leveling effect and efficiency of the light-shielding layer 30 on the metal layer 50. This avoids the problem that the local regions of the metal layer 50 are not covered with the light-shielding layer 30 or that the semi-fluid light-shielding layer 30 has uneven thickness on the surface of the metal layer 50, thereby enabling uniform light shielding of the light-shielding layer 30, ensuring the integrated black effect of the display panel, and further enhancing the user experience.

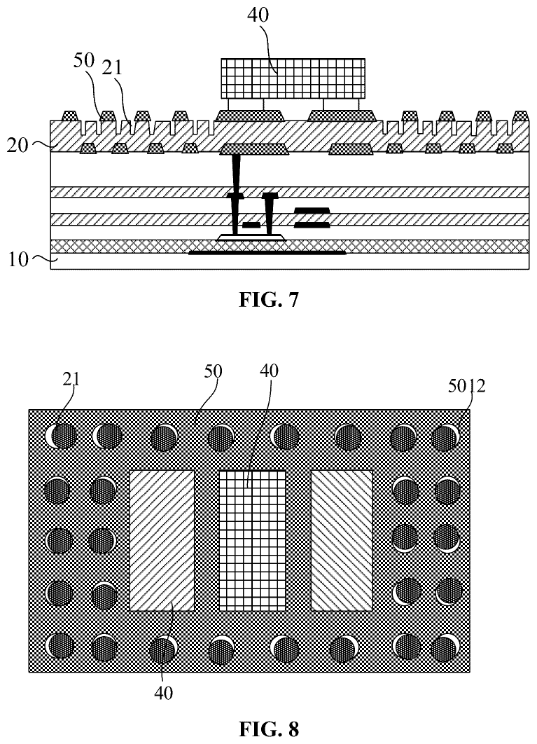

In one or more embodiments, FIG. 6 is another top view of a display panel according to embodiments of the present disclosure, and FIG. 7 is a cross-sectional view of the display panel corresponding to FIG. 6. Referring to FIGS. 6 and 7, the orthographic projections of the groove structures 21 on the base substrate 10 are located within the orthographic projections of the second openings 5012 on the base substrate 10 respectively, and for at least some groove structures 21 and at least some second openings 5012, the geometric center of the orthographic projection of a groove structure 21 on the base substrate 10 does not coincide with the geometric center of the orthographic projection of a second opening 5012 on the base substrate 10.

Specifically, the orthographic projections of the groove structures 21 on the base substrate 10 are located within the orthographic projections of the second openings 5012 on the base substrate 10 respectively. That is to say, the projection region of the groove structure 21 is smaller than the projection region of the second opening 5012. In other words, from a top view, the groove structure 21 is entirely located within the second opening 5012, and the size of the second opening 5012 is larger than the size of the groove structure 21. This can ensure that the groove structures 21 are fully exposed from the first metal portion 501 such that when the semi-fluid light-shielding layer 30 is prepared, the light-shielding layer 30 can fill the groove structures 21 from the first metal portion 501 via the second openings 5012. As a result, the groove structures 21 are filled with the parts of the light-shielding layer 30, which lowers the fluid level of the light-shielding layer 30 around the light-emitting element 40, thereby lowering the probability of the light-shielding layer 30 creeping onto the sidewall of the light-emitting element 40 due to the capillary effect and ensuring the light-emitting efficiency of the light-emitting element 40.

Additionally, in this embodiment, for the at least some groove structures 21 and the at least some second openings 5012, the geometric center of the orthographic projection of the groove structure 21 on the base substrate 10 does not coincide with the geometric center of the orthographic projection of the second opening 5012 on the base substrate 10. That is to say, the projection regions of the groove structures 21 and the projection regions of the second openings 5012 may be shown in FIG. 6. That is, the groove structures 21 are located within the second openings 5012 respectively. However, the specific positions of the groove structures 21 within the second openings 5012 may be different-some groove structures 21 may be located on the left sides of second openings 5012 respectively, some groove structures 21 may be located on the right sides of second openings 5012 respectively, some groove structures 21 may be located on the upper sides of second openings 5012 respectively, some groove structures 21 may be located on the lower sides of second openings 5012 respectively, some groove structures 21 may be located on the diagonal sides of second openings 5012 respectively, or, certainly, some groove structures 21 may be located at the centers of second openings 5012 respectively. It can be seen that this configuration corresponds to the case where the metal layer 50 and the groove structures 21 are prepared separately, that is, the groove structures 21 are prepared first, followed by the preparation of the second openings 5012 on the metal layer 50. In this case, in addition to that the projection regions of the groove structures 21 are located at the centers of the projection regions of the second openings 5012, that is, the geometric centers of the projection regions of the groove structures 21 coincide with the geometric centers of the projection regions of the second openings 5012, the geometric centers of the projection regions of the groove structures 21 do not coincide with the geometric centers of the projection regions of the second openings 5012 in all other cases. Such a configuration does not adversely affect the respective filling of the groove structures 21 with the parts of the light-shielding layer 30, that is, the groove structures 21 can normally accommodate the light-shielding layer 30, thereby lowering the fluid level of the light-shielding layer 30 around the light-emitting element 40 and ensuring the light-emitting efficiency of the light-emitting element 40.

In this embodiment, when the metal layer 50 and the groove structures 21 are prepared separately, that is, after the insulating layer 20 is formed on the base substrate 10, the groove structures 21 may be ultimately formed on the surface of the insulating layer 20 through processes such as etching and development of the insulating layer 20. After the groove structures 21 are formed, the entire metal layer 50 is then formed on the surfaces of sides of the groove structures 21 facing away from the base substrate 10. After the metal layer 50 is formed, since the groove structures 21 located on one side of the metal layer 50 facing the base substrate 10 are intended to accommodate the parts of the light-shielding layer 30 respectively, the groove structures 21 need to be exposed. However, due to the full-layer configuration of the metal layer 50, the groove structures 21 are covered, and the specific positions of the groove structures 21 on the metal layer 50 cannot be accurately identified during the patterning process for forming the second openings 5012 on the metal layer 50. Therefore, to ensure that the groove structures 21 are fully exposed, high alignment precision for the second openings 5012 on the metal layer 50 is not required. In other words, the second openings 5012 are formed slightly larger on the metal layer 50—as shown in FIG. 6—so as to ensure that the groove structures 21 can be properly exposed. This avoids the case where, due to misalignment of the second openings 5012 on the metal layer 50 with the groove structures 21, parts of the metal layer 50 fill the groove structures 21. The case prevents the groove structures 21 from accommodating the nearby semi-fluid light-shielding layer 30 and causes the light-shielding layer 30 to creep onto the sidewall of the light-emitting element 40, thereby adversely affecting the light-emitting efficiency of the light-emitting element 40.

In one or more embodiments, FIG. 8 is another top view of a display panel according to embodiments of the present disclosure. Referring to FIG. 8, the orthographic projections of the groove structures 21 on the base substrate 10 partially overlap the orthographic projections of the second openings 5012 on the base substrate 10 respectively, and at least parts of the metal layer 50 are located within the groove structures 21 respectively.

Specifically, the orthographic projections of the groove structures 21 on the base substrate 10 partially overlap the orthographic projections of the second openings 5012 on the base substrate 10 respectively, that is, the projection region of the groove structure 21 partially overlaps the projection region of the second opening 5012, that is, a part of the projection region of the groove structure 21 overlaps a part of the projection region of the second opening 5012 while the other part of the projection region of the groove structure 21 does overlap the other part of the projection region of the second opening 5012. In other words, in a direction perpendicular to an extension direction of the base substrate 10, the edge of the groove structure 21 is not fully aligned with the edge of the second opening 5012. Only part of the second opening 5012 is aligned with part of the groove structure 21 such that this part of the groove structure 21 is exposed, while the remaining part of the groove structure 21 is not exposed, and part of the first metal portion 501 covers the groove structure 21. The advantage of such a configuration is that the exposed part of the groove structure 21 can accommodate the semi-fluid light-shielding layer 30 near the light-emitting element 40, thereby lowering the fluid level of the light-shielding layer 30 near the light-emitting element 40. This prevents the fluid level of the light-shielding layer 30 from becoming high and thereby prevents the light-shielding layer 30 from creeping onto the light-emitting element 40 due to the capillary effect caused by the microstructure on the surface of the light-emitting element 40, which could otherwise adversely affect the light-emitting efficiency of the light-emitting element 40.

It is also to be further noted that, while the orthographic projection of the groove structure 21 on the base substrate 10 partially overlaps the orthographic projection of the second opening 5012 on the base substrate 10, at least part of the metal layer 50 is located within the groove structure 21. In other words, when the groove structure 21 and the second opening 5012 are not fully aligned, and there is a positional offset, only the part of the groove structure 21 is exposed, and the unexposed part of the groove structure 21 is covered by the first metal portion 501. As a result, the first metal portion 501 extends into the groove structure 21 and is at least present on the sidewall of the groove structure 21. Based on this, the provision of the light-shielding layer 30 does not interfere with the function of the groove structure 21 in accommodating part of the light-shielding layer 30. Therefore, the light-shielding layer 30 cannot creep onto the sidewall of the light-emitting element 40, thus avoiding the adverse effect on the light-emitting effect of the light-emitting element 40.

During the preparation process, the first metal portion 501 of the metal layer 50 may be patterned using a predefined mask, where the position of the predefined mask overlaps the position of the groove structure 21 to a certain extent. As a result, the second opening 5012 formed through the patterning process partially overlaps the groove structure 21, and the metal layer 30 in the overlapping region extends into the groove structure 21 and is located in the groove structure 21, thereby ensuring the accommodation function of the groove structure 21.

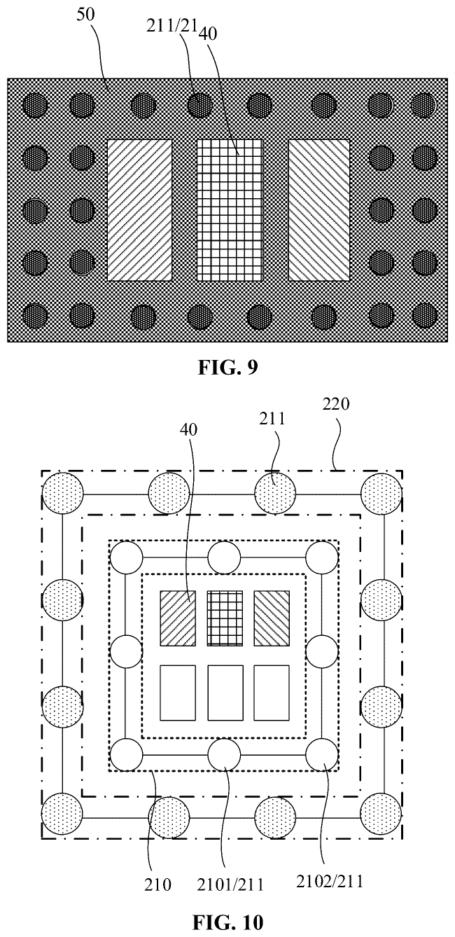

In one or more embodiments, FIG. 9 is another top view of a display panel according to embodiments of the present disclosure. Referring to FIGS. 1 and 9, the groove structures 21 include multiple blind holes 211; in a direction perpendicular to the base substrate 10, the depth of a blind hole 211 of the multiple blind holes 211 is smaller than the thickness of the insulating layer 20.

The blind hole 211 refers to a hole that is formed to a specific depth without penetrating through the other end of the insulating layer 20 and has only one open end and a closed bottom. In this embodiment, the groove structures 21 include the multiple blind holes 211. The blind holes 211 may be arranged in an array, around the light-emitting element 40, between two adjacent light-emitting elements 40, or between different pixel units. A pixel unit may include at least two adjacent light-emitting elements 40. Certainly, the blind holes 211 may also be arranged in an irregular pattern. The specific arrangement may be determined based on the actual conditions and is not limited herein.

It is to be noted that the size of the blind hole 211 may also be configurable, that is, the blind holes 211 may be arranged in at least two concentric circles surrounding the light-emitting element 40. In such a case, the size of a blind hole 211 in the outer circle may be larger than the size of a blind hole 211 in the inner circle. Certainly, the size of the blind hole 211 in the inner circle may also be larger than the size of the blind hole 211 in the outer circle. Under the premise that the blind holes 211 in this embodiment are configured to accommodate the parts of the light-shielding layer 30 respectively, lowering the fluid level of the light-shielding layer 30 around the light-emitting element 40, lowering the probability of the light-shielding layer 30 creeping onto the sidewall of the light-emitting element 40, and thereby ensuring the light-emitting efficiency of the light-emitting element 40 and the display effect of the display panel, the size of the blind hole 211 and the arrangement of the blind holes 211 are not specifically limited and may be determined based on the actual conditions.

It is to be understood that, with respect to the shape of the blind hole 211, the projection shape of the blind hole 211 on the base substrate 10 may be circular, square, rectangular, triangular, rhombic, semi-circular, semi-elliptical, or another suitable shape, which is not specifically limited in this embodiment under the premise that the core inventive concept of the present disclosure is not affected. For ease of understanding and explanation, the following descriptions of the blind hole 211 are specifically provided based on the example in which the shape of the blind hole 211 is circular.

It is also to be understood that, from a cross-sectional view of the blind hole 211, the sidewall of the blind hole 211 may be vertical, inclined inward or outward, or curved, which is not specifically limited in this embodiment under the premise that the core inventive concept of the present disclosure is not affected. To ensure a better accommodation effect, the sidewall of the blind hole 211 may be inclined inward, that is, in the shape of a regular trapezoid. Moreover, if an opening of the blind hole 211 is small, this can reduce the area occupied during the hole-forming process, thereby avoiding an excessive area that affects a routing region for wiring.

It is also to be noted that, in the direction perpendicular to the base substrate 10, the depth of the blind hole 211 is smaller than the thickness of the insulating layer 20. In other words, the thickness of the insulating layer 20 is larger than the depth of the blind hole 211, that is, the depth of the blind hole 211 does not reach a bottom end on the other side of the insulating layer 20. The opening of the blind hole 211 is directed towards the side of the insulating layer 20 facing away from the base substrate 10. Such a configuration can ensure that, during inkjet printing of the light-shielding layer 30, the light-shielding layer 30 only fills the blind hole 211 and does not flow to the base substrate 10 through the insulating layer 20. As a result, signal interference with the light-emitting element 40 can be avoided, and the risk of cracking in the light-shielding layer 30 due to external stress or other factors can be reduced, thereby enhancing the stability of the light-shielding layer 30.

In one or more embodiments, with continued reference to FIG. 9, the orthographic projections of the multiple blind holes 211 on the base substrate 10 are arranged around the orthographic projection of the light-emitting element 40 on the base substrate 10.

Specifically, referring to FIG. 9, the blind holes 211 surround the periphery of the light-emitting element 40. In other words, the light-emitting element 40 is located within a region encircled by the blind holes 211, and there is a certain distance from the edge of each blind hole 211 to the light-emitting element 40. The advantage of such a configuration is that, during the preparation of the semi-fluid light-shielding layer 30, the light-shielding layer 30 preferentially fills the blind holes 211 around the periphery of the light-emitting element 40, and only after the blind holes 211 are filled with the light-shielding layer 30 is the remaining light-shielding layer 30 deposited on the surface of the metal layer 50. As such, the light-shielding layer 30 flowing in from all directions can be accommodated by the blind holes 211, which significantly lowers the fluid level of the light-shielding layer 30 near the light-emitting element 40. As a result, this prevents the fluid level of the light-shielding layer 30 from becoming high, thereby prevents the light-shielding layer 30 from creeping onto the light-emitting element 40 due to the capillary effect caused by the microstructure on the surface of the light-emitting element 40, even preventing the light-shielding layer 30 from creeping onto the light-emitting element 40, and thus ensuring the light-emitting efficiency of the light-emitting element 40.

In one or more embodiments, FIG. 10 is another top view of a display panel according to embodiments of the present disclosure. Referring to FIG. 10, the multiple blind holes 211 at least form a first blind hole group 210 and a second blind hole group 220; the orthographic projections of blind holes 211 in the first blind hole group 210 on the base substrate 10 are arranged around the orthographic projection of the light-emitting element 40 on the base substrate 10, and the orthographic projections of blind holes 211 in the second blind hole group 220 on the base substrate 10 are arranged around the orthographic projection of the first blind hole group 210 on the base substrate 10.

Specifically, the orthographic projections of the blind holes 211 in the first blind hole group 210 on the base substrate 10 are arranged around the orthographic projection of the light-emitting element 40 on the base substrate 10, and the orthographic projections of the blind holes 211 in the second blind hole group 220 on the base substrate 10 are arranged around the orthographic projection of the first blind hole group 210 on the base substrate 10. That is, the first blind hole group 210 surrounds the periphery of the light-emitting element 40, and the second blind hole group 220 surrounds the periphery of the first blind hole group 210. In other words, from the outside to the inside, the arrangement of the first blind hole group 210, the second blind hole group 220, and the light-emitting element 40 is: the second blind hole group 220, the first blind hole group 210, and the light-emitting element 40, that is, the second blind hole group 220 is at the outermost position while the light-emitting element 40 is at the innermost position. Since the first blind hole group 210 and the second blind hole group 220 each include multiple blind holes 211, the advantage of such a configuration is that, during inkjet printing of the light-shielding layer 30, the blind holes 211 in the second blind hole group 220 and the blind holes 211 in the first blind hole group 210 accommodate the semi-fluid light-shielding layer 30 in the region near the light-emitting element 40. This can prevent the light-shielding layer 30 from self-leveling, more effectively lower the fluid level of the light-shielding layer 30 in the region near the light-emitting element 40, and form the fluid level difference between the region near the light-emitting element 40 and the region away from the light-emitting element 40. As a result, this increases the difficulty of the light-shielding layer 30 in the region near the light-emitting element 40 creeping onto the light-emitting element 40 so that the light-shielding layer 30 cannot creep onto the light-emitting element 40, thereby ensuring that the light-emitting element 40 is free of obstruction, improving the light-emitting efficiency of the light-emitting element 40, and enhancing the display effect of the display panel.

In one or more embodiments, with continued reference to FIG. 10, the first blind hole group 210 includes adjacent first blind hole 2101 and second blind hole 2102; a line connecting the center of the first blind hole 2101 and the center of the second blind hole 2102 is a first connection line, and a direction perpendicular to the first connection line is a first direction; along the first direction, the center of a blind hole 211 of at least one blind hole 211 in the second blind hole group 220 is located between the first blind hole 2101 and the second blind hole 2102.

Specifically, the line connecting the center of the first blind hole 2101 and the center of the second blind hole 2102 is the first connection line, that is, the first connection line may be a connection line in an X direction or a connection line in a Y direction. Specifically, when the first blind hole 2101 is located at a vertex position of the first blind hole group 210, and the second blind hole 2102 is located to the left or right of the first blind hole 2101, or when the second blind hole 2102 is located at a vertex position of the first blind hole group 210, and the first blind hole 2101 is located to the left or right of the second blind hole 2102, the first connection line formed by connecting the center of the first blind hole 2101 and the center of the second blind hole 2102 is the connection line in the X direction. When the first blind hole 2101 is located at a vertex position of the first blind hole group 210, and the second blind hole 2102 is located above or below the first blind hole 2101, or when the second blind hole 2102 is located at a vertex position of the first blind hole group 210, and the first blind hole 2101 is located above or below the second blind hole 2102, the first connection line formed by connecting the center of the first blind hole 2101 and the center of the second blind hole 2102 is the connection line in the Y direction. The specific direction may be determined based on the actual conditions and is not limited herein. Additionally, the direction perpendicular to the first connection line is the first direction. That is, when the first connection line is the connection line in the X direction, the corresponding first direction is the Y direction; when the first connection line is the connection line in the Y direction, the corresponding first direction is the X direction.

It is to be noted that, along the first direction, the center of the blind hole 211 of the at least one blind hole 211 in the second blind hole group 220 is located between the first blind hole 2101 and the second blind hole 2102. That is, in the first direction, the at least one blind hole 211 in the second blind hole group 220 in the periphery is located between the first blind hole 2101 and the second blind hole 2102. In other words, the relative arrangement between two adjacent blind holes in the first blind hole group 210 and two adjacent blind holes in the second blind hole group 220 is a staggered arrangement rather than an arrangement in which blind holes 211 in the first blind hole group 210 and the second blind hole group 220 are aligned with each other. Such a staggered arrangement between blind holes in the inner circle and blind holes in the outer circle can allow the light-shielding layer 30 to sequentially fill the staggered blind holes 211 in the second blind hole group 220 and the first blind hole group 210 when the semi-fluid light-shielding layer 30 is formed, thereby increasing the difficulty of the light-shielding layer 30 flowing into the region where the light-emitting element 40 is located through a gap between two adjacent blind holes 211, preventing the light-shielding layer 30 from prematurely contacting the light-emitting element 40, and thus increasing the difficulty of the light-shielding layer 30 in the region near the light-emitting element 40 creeping onto the light-emitting element 40. As a result, the light-shielding layer 30 cannot creep onto the light-emitting element 40, improving the light-emitting efficiency of the light-emitting element 40 and enhancing the display effect of the display panel.

In one or more embodiments, with continued reference to FIG. 10, the diameter of a blind hole 211 in the first blind hole group 210 is smaller than the diameter of a blind hole 211 in the second blind hole group 220.

Specifically, the diameter of the blind hole 211 in the first blind hole group 210 is set to be smaller than the diameter of the blind hole 211 in the second blind hole group 220, that is, each blind hole 211 in the second blind hole group 220 located in the periphery has a large diameter, and each blind hole 211 in the first blind hole group 210 located in the inner circle has a small diameter. In other words, the blind holes in the second blind hole group 220 that is farther from the light-emitting element 40 each have a large diameter, while the blind holes in the first blind hole group 210 that is closer to the light-emitting element 40 each have a small diameter. The advantage of such a configuration is that, during inkjet printing to form the light-shielding layer 30, a relatively large amount of the light-shielding layer 30 preferentially fills the blind holes of the second blind hole group 220 that each have a relatively large diameter, while a relatively small amount of the light-shielding layer 30 fills the blind holes 211 of the first blind hole group 210 that each have a relatively small diameter. As a result, the second blind hole group 220 farther from the light-emitting element 40 can accommodate more of the light-shielding layer 30 while the first blind hole group 210 closer to the light-emitting element 40 can accommodate less of the light-shielding layer 30, thereby precisely controlling the distribution range of the light-shielding layer 30, preventing excessive deposition of the light-shielding layer 30 around the periphery of the light-emitting element 40, and ensuring the light-emitting efficiency of the light-emitting element 40.

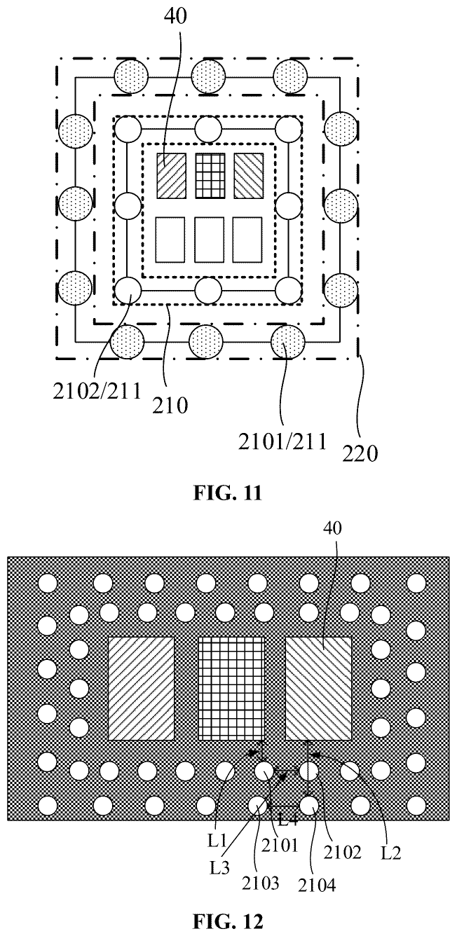

In one or more embodiments, FIG. 11 is another top view of a display panel according to embodiments of the present disclosure. Referring to FIGS. 10 and 11, the multiple blind holes 211 include first blind holes 2101 and second blind holes 2102; in a direction parallel to the base substrate 10, the distance from a first blind hole 2101 of the first blind holes 2101 to the light-emitting element 40 is larger than the distance from a second blind hole 2102 of the second blind holes 2102 to the light-emitting element 40, and the diameter of the first blind hole 2101 is larger than the diameter of the second blind hole 2102.

Specifically, in the direction parallel to the base substrate 10, the distance from the first blind hole 2101 to the light-emitting element 40 is larger than the distance from the second blind hole 2102 to the light-emitting element 40, that is, the second blind hole 2102 is closer to the light-emitting element 40, and the first blind hole 2101 is farther from the light-emitting element 40. It is to be understood that the shape enclosed by the first blind holes 2101 surrounds the light-emitting element 40, and the shape enclosed by the second blind holes 2102 surrounds the shape enclosed by the first blind holes 2101. In this case, the positions of the first blind holes 2101 and the second blind holes 2102 may be arranged in an aligned manner as shown in FIG. 11. In other words, using the centrally located blind holes in the bottom two rows shown in FIG. 11 as an example, a first blind hole 2101 and a second blind hole 2102 are aligned in a column direction, and the column direction is a direction perpendicular to an arrangement direction of the light-emitting elements 40. Alternatively, using the centrally located blind holes in the leftmost two columns as an example, a first blind hole 2101 and a second blind hole 2102 are aligned in a row direction, and the row direction is a direction parallel to the arrangement direction of the light-emitting elements 40. In addition to the aligned arrangement, the preceding arrangement may also be the staggered arrangement of the first blind hole group 210 and the second blind hole group 220 as shown in FIG. 10. The specific arrangement may be determined based on the actual conditions, which is limited in this embodiment under the premise that the core inventive concept of the present disclosure is not affected. It is to be understood that the blind hole in the first blind hole group 210 shown in FIG. 10 is the same as the second blind hole 2102 shown in FIG. 11, and the blind hole in the second blind hole group 220 shown in FIG. 10 is the same as the first blind hole 2101 shown in FIG. 11. It is to be noted that the diameter of the first blind hole 2101 is larger than the diameter of the second blind hole 2102. In other words, the first blind hole 2101 farther from the light-emitting element 40 has a large diameter, while the second blind hole 2102 closer to the light-emitting element 40 has a small diameter. The advantage of such a configuration is that, during inkjet printing to form the light-blocking layer 30, a relatively large amount of the light-blocking layer 30 preferentially fills the first blind holes 2101 with a relatively large diameter, while a small amount of the light-blocking layer 30 fills the second blind holes 2102 with a relatively small diameter. As a result, the first blind holes 2101 can accommodate more of the light-blocking layer 30 while the second blind holes 2102 can accommodate less of the light-blocking layer 30, thereby precisely controlling the distribution range of the light-blocking layer 30, preventing excessive flow of the light-blocking layer 30 toward the periphery of the light-emitting element 40, and ensuring the light-emitting efficiency of the light-emitting element 40. Additionally, as shown in FIG. 11, the first blind hole group 210 and the second blind hole group 220 are arranged in an aligned manner in the direction parallel to the base substrate 10, that is, several groups of blind holes are disposed around the periphery of the light-emitting element 40 so that the first blind holes 2101 and the second blind holes 2102 sequentially surround the light-emitting element 40 from the outside to the inside. This allows the first blind holes 2101 and the second blind holes 2102 to accommodate the light-blocking layer 30 from the outside to the inside, thereby lowering the probability of the light-blocking layer 30 creeping onto the periphery of the light-emitting element 40 and improving the light-emitting efficiency of the light-emitting element 40. Based on the arrangement shown in FIG. 11, the first blind hole group 210 and the second blind hole group 220 are staggered in the direction parallel to the base substrate 10 as shown in FIG. 10, forming a denser arrangement. As such, the light-blocking layer 30 passes through the first blind holes 2101 in the outer circle and then enters the second blind holes 2102 that are in the inner circle and located in gaps between two adjacent first blind holes 2101, and the second blind holes 2102 block the light-blocking layer 30 in these gaps. In other words, the first blind holes 2101 and the second blind holes 2102 accommodate more of the light-blocking layer 30 from all directions, thereby greatly reducing the amount of the light-blocking layer 30 flowing toward the periphery of the light-emitting element 40, lowering the probability of the light-blocking layer 30 creeping onto the periphery of the light-emitting element 40, and improving the light-emitting efficiency of the light-emitting element 40.

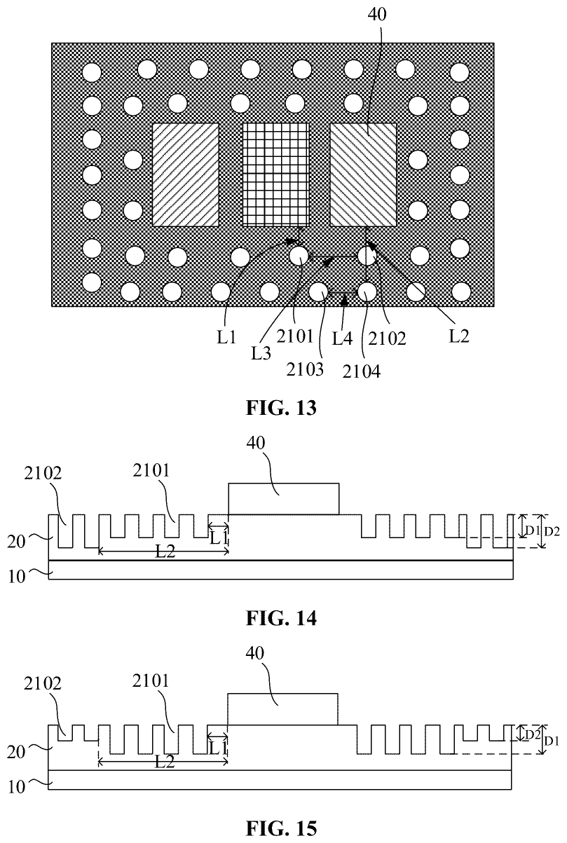

In one or more embodiments, FIG. 12 is a first diagram of the arrangement of blind holes according to embodiments of the present disclosure, and FIG. 13 is a second diagram of the arrangement of blind holes according to embodiments of the present disclosure. Referring to FIGS. 12 and 13, the multiple blind holes 211 include the first blind holes 2101, the second blind holes 2102, third blind holes 2103, and fourth blind holes 2104; the first blind hole 2101 is adjacent to the second blind hole 2102, and a third blind hole 2103 of the third blind holes 2103 is adjacent to a fourth blind hole 2104 of the fourth blind holes 2104; in the direction parallel to the base substrate 10, the distance from one of the first blind hole 2101 or the second blind hole 2102 that is closest to the light-emitting element 40 to the light-emitting element 40 is L1; the distance from one of the third blind hole 2103 or the fourth blind hole 2104 that is closest to the light-emitting element 40 to the light-emitting element 40 is L2; the distance from the first blind hole 2101 to the second blind hole 2102 is L3; the distance from the third blind hole 2103 to the fourth blind hole 2104 is L4; L1<L2; L3<L4, or L3>L4.

Specifically, in the direction parallel to the base substrate 10, the distance from the one of the first blind hole 2101 or the second blind hole 2102 that is closest to the light-emitting element 40 to the light-emitting element 40 is L1, the distance from the one of the third blind hole 2103 or the fourth blind hole 2104 that is closest to the light-emitting element 40 to the light-emitting element 40 is L2, and L1<L2. In other words, the first blind hole 2101 and the second blind hole 2102 are closer to the light-emitting element 40 while the third blind hole 2103 and the fourth blind hole 2104 are farther from the light-emitting element 40. It is to be understood that the third blind hole 2103 and the fourth blind hole 2104 are located in a peripheral region of the first blind hole 2101 and the second blind hole 2102. As such, the light-blocking layer 30 preferentially fills the third blind holes 2103 and the fourth blind holes 2104 that are farther from the light-emitting element 40, and then fills the first blind holes 2101 and the second blind holes 2102 that are closer to the light-emitting element 40. This allows the third blind holes 2103 and the fourth blind holes 2104 to accommodate more of the light-blocking layer 30, and the first blind holes 2101 and the second blind holes 2102 to accommodate less of the light-blocking layer 30, thereby precisely controlling the distribution range of the light-blocking layer 30, preventing excessive flow of the light-blocking layer 30 toward the periphery of the light-emitting element 40, and ensuring the light-emitting efficiency of the light-emitting element 40.

It is to be noted that, referring to FIG. 12, for the semi-fluid light-shielding layer 30 with poor fluidity, the poor fluidity indicates that the fluid level of the light-shielding layer 30 has height differences and is not at the same height. In this case, to ensure the light-emitting efficiency of the light-emitting element 40, in this embodiment, the distance from the first blind hole 2101 to the second blind hole 2102 is L3, the distance from the third blind hole 2103 to the fourth blind hole 2104 is L4, and L3<L4, that is, the distance between the first blind hole 2101 and the second blind hole 2102 that are closer to the light-emitting element 40 is smaller than the distance between the third blind hole 2103 and the fourth blind hole 2104 that are farther from the light-emitting element 40. In other words, the closer the distance to the light-emitting element 40, the higher the arrangement density of blind holes 211, and the denser the distribution of the blind holes 211; the farther the distance from the light-emitting element 40, the lower the arrangement density of blind holes 211, and the sparser the distribution of the blind holes 211. Such an arrangement density can ensure that the blind holes 211 can accommodate more of the semi-fluid light-shielding layer 30 so that more of the light-shielding layer 30 flows into the blind holes 211 closer to the light-emitting element 40, thereby enabling the fluid level of the light-shielding layer 30 closer to the light-emitting element 40 to be lower and reducing the thickness of the light-shielding layer 30 deposited on the surface of the insulating layer 20. To a certain extent, it can be understood that the light-emitting element 40 is physically isolated from the light-shielding layer 30 around the light-emitting element 40, thereby preventing the light-shielding layer 30 from prematurely contacting the light-emitting element 40, preventing the light-shielding layer 30 from creeping onto the sidewall of the light-emitting element 40, increasing the difficulty for the light-shielding layer 30 to creep, ensuring the light-emitting efficiency of the light-emitting element 40, and enhancing the display effect of the display panel.

It is also to be noted that, referring to FIG. 13, for the semi-fluid light-shielding layer 30 with good fluidity, the good fluidity indicates that the fluid level of the light-shielding layer 30 may have no height difference, and the fluid level of the light-shielding layer 30 located on the metal layer 50 is at the same height. In this case, to ensure the light-emitting efficiency of the light-emitting element 40, in this embodiment, the distance from the first blind hole 2101 to the second blind hole 2102 is L3, the distance from the third blind hole 2103 to the fourth blind hole 2104 is L4, and L3>L4, that is, the distance between the first blind hole 2101 and the second blind hole 2102 that are closer to the light-emitting element 40 is larger than the distance between the third blind hole 2103 and the fourth blind hole 2104 that are farther from the light-emitting element 40. In other words, the closer the distance to the light-emitting element 40, the lower the arrangement density of blind holes 211, and the sparser the distribution of the blind holes 211; the farther the distance from the light-emitting element 40, the higher the arrangement density of blind holes 211, and the denser the distribution of the blind holes 211. Such an arrangement density can ensure that the blind holes 211 can accommodate more of the semi-fluid light-shielding layer 30 so that more of the light-shielding layer 30 stays in the blind holes 211 farther from the light-emitting element 40, thereby enabling the fluid level of the light-shielding layer 30 closer to the light-emitting element 40 to be lower and reducing the thickness of the light-shielding layer 30 deposited on the surface of the insulating layer 20. To a certain extent, it can be understood that the light-emitting element 40 is physically isolated from the light-shielding layer 30 around the light-emitting element 40, thereby preventing the light-shielding layer 30 from prematurely contacting the light-emitting element 40, preventing the light-shielding layer 30 from creeping onto the sidewall of the light-emitting element 40, increasing the difficulty for the light-shielding layer 30 to creep, ensuring the light-emitting efficiency of the light-emitting element 40, and enhancing the display effect of the display panel.

In one or more embodiments, FIG. 14 is a diagram illustrating the structure in which the depth of a first blind hole is smaller than the depth of a second blind hole according to embodiments of the present disclosure, and FIG. 15 is a diagram illustrating the structure in which the depth of a first blind hole is larger than the depth of a second blind hole according to embodiments of the present disclosure. Referring to FIGS. 14 and 15, the multiple blind holes 211 include the first blind holes 2101 and the second blind holes 2102; in the direction parallel to the base substrate 10, the distance from the first blind hole 2101 to the light-emitting element 40 is L1, and the distance from the second blind hole 2102 to the light-emitting element 40 is L2; in the direction perpendicular to the base substrate 10, the depth of the first blind hole 2101 is D1, and the depth of the second blind hole is D2; L1<L2; D1<D2, or D1>D2.

Specifically, in the direction parallel to the base substrate 10, the distance from the first blind hole 2101 to the light-emitting element 40 is L1, the distance from the second blind hole 2102 to the light-emitting element 40 is L2, and L1<L2. In other words, the first blind hole 2101 is closer to the light-emitting element 40, and the second blind hole 2102 is farther from the light-emitting element 40. It can also be understood that the second blind hole 2102 is located in a peripheral region of the first blind hole 2101. As such, the light-shielding layer 30 preferentially fills the second blind holes 2102 farther from the light-emitting element 40, and then fills the first blind hole 2101 closer to the light-emitting element 40. This lowers the fluid level of the light-shielding layer 30 around the periphery of the light-emitting element 40 so that the fluid level of the light-shielding layer 30 farther from the light-emitting element 40 is higher than the fluid level of the light-shielding layer 30 closer to the light-emitting element 40, thereby preventing the light-shielding layer 30 from creeping onto the sidewall of the light-emitting element 40, ensuring the light-emitting efficiency of the light-emitting element 40, and enhancing the display effect of the display panel.

It is to be noted that, referring to FIG. 14, in the direction perpendicular to the base substrate 10, the depth of the first blind hole 2101 is D1, the depth of the second blind hole 2102 is D2, and D1<D2, that is, the depth of the first blind hole 2101 closer to the light-emitting element 40 is smaller than the depth of the second blind hole 2102 farther from the light-emitting element 40. In other words, the farther a blind hole 211 from the light-emitting element 40, the deeper the blind hole 211; the closer the blind hole 211 to the light-emitting element 40, the shallower the blind hole 211. Such a configuration can ensure that the first blind holes 2101 and the second blind holes 2102 can accommodate more of the semi-fluid light-shielding layer 30 so that more of the light-shielding layer 30 flows into the second blind holes 2102 farther from the light-emitting element 40, thereby enabling the fluid level of the light-shielding layer 30 closer to the light-emitting element 40 to be lower and reducing the thickness of the light-shielding layer 30 deposited on the surface of the insulating layer 20. To a certain extent, it can be understood that the light-emitting element 40 is physically isolated from the light-shielding layer 30 around the light-emitting element 40, thereby preventing the light-shielding layer 30 from prematurely contacting the light-emitting element 40, preventing the light-shielding layer 30 from creeping onto the sidewall of the light-emitting element 40, increasing the difficulty for the light-shielding layer 30 to creep, ensuring the light-emitting efficiency of the light-emitting element 40, and enhancing the display effect of the display panel.

It is also to be noted that, referring to FIG. 15, in the direction perpendicular to the base substrate 10, the depth of the first blind hole 2101 is D1, the depth of the second blind hole 2102 is D2, and D1>D2, that is, the depth of the first blind hole 2101 closer to the light-emitting element 40 is larger than the depth of the second blind hole 2102 farther from the light-emitting element 40. In other words, the farther a blind hole 211 from the light-emitting element 40, the shallower the blind hole 211; the closer the blind hole 211 to the light-emitting element 40, the deeper the blind hole 211. Such a configuration can ensure that the first blind holes 2101 and the second blind holes 2102 can accommodate more of the semi-fluid light-shielding layer 30 so that more of the light-shielding layer 30 flows into the first blind holes 2102 closer to the light-emitting element 40, thereby enabling the fluid level of the light-shielding layer 30 closer to the light-emitting element 40 to be lower and reducing the thickness of the light-shielding layer 30 deposited on the surface of the insulating layer 20. To a certain extent, it can be understood that the light-emitting element 40 is physically isolated from the light-shielding layer 30 around the light-emitting element 40, thereby preventing the light-shielding layer 30 from prematurely contacting the light-emitting element 40, preventing the light-shielding layer 30 from creeping onto the sidewall of the light-emitting element 40, increasing the difficulty for the light-shielding layer 30 to creep, ensuring the light-emitting efficiency of the light-emitting element 40, and enhancing the display effect of the display panel.

In one or more embodiments, with continued reference to FIGS. 9 to 13, the orthographic projection of the blind hole 211 on the base substrate 10 is circular, elliptical, or polygonal, and/or the orthographic projection of the blind hole 211 on a plane perpendicular to the base substrate 10 is semicircular, semi-elliptical, rectangular, or trapezoidal.

Specifically, the orthographic projection of the blind hole 211 on the base substrate 10 is circular, elliptical, or polygonal, that is, when the blind hole 211 is provided, the projection shape of the blind hole 211 may be circular, elliptical, or polygonal, which may be set based on the actual conditions and is not limited herein under the premise that the blind holes 211 can accommodate more of the light-shielding layer 30. Additionally, the orthographic projection of the blind hole 211 on the plane perpendicular to the base substrate 10 is semicircular, semi-elliptical, rectangular, or trapezoidal, that is, the sidewall of the blind hole 211 may be arc-shaped, a vertical line, or inclined inward or outward, which may be set based on the actual conditions and is not limited herein under the premise that the blind holes 211 can accommodate more of the light-shielding layer 30.

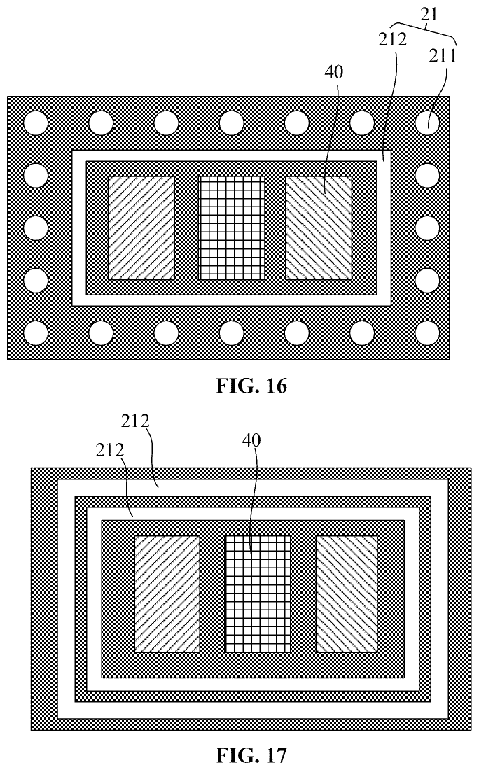

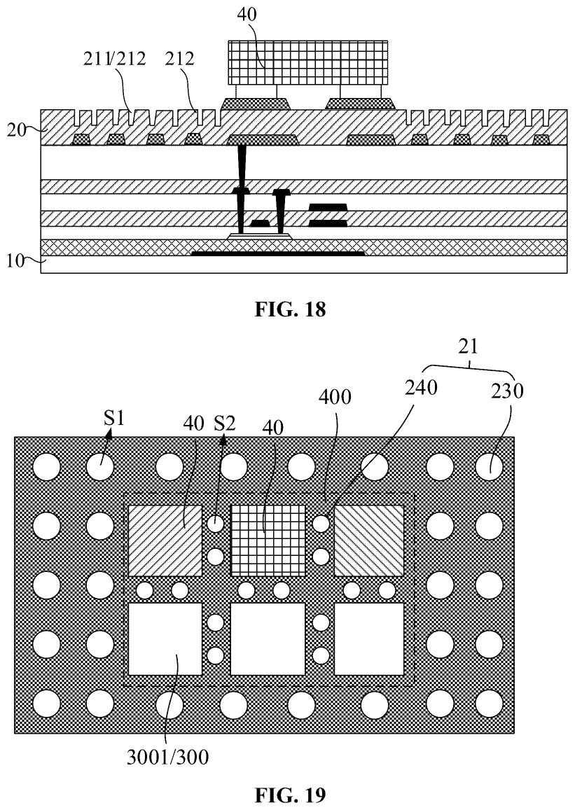

In one or more embodiments, FIG. 16 is another top view of a display panel according to embodiments of the present disclosure, FIG. 17 is another top view of a display panel according to embodiments of the present disclosure, and FIG. 18 is a cross-sectional view of the display panel shown in FIG. 16 or FIG. 17. Referring to FIGS. 16 to 18, the groove structures 21 include at least one annular groove 212, the orthographic projection of an annular groove 212 of the at least one annular groove 212 on the base substrate 10 surrounds the orthographic projection of the light-emitting element 40 on the base substrate 10, and in the direction perpendicular to the base substrate 10, the depth of the annular groove 212 is smaller than the thickness of the insulating layer 20.

The annular groove 212 is configured to accommodate more of the light-shielding layer 30.

Specifically, referring to FIG. 16, the groove structures 21 include the at least one annular groove 212, that is, the groove structures 21 may include one annular groove 212, or may include two or three annular grooves 212. When the groove structures 21 include the two or three annular grooves 212, the annular grooves 212 may be arranged in a surrounding manner, that is, a second annular groove 212 is provided around the periphery of a first annular groove 212, and a third annular groove 212 is provided around the periphery of the second annular groove 212, which may be determined based on the actual conditions. In this embodiment, FIG. 16 exemplarily illustrates the structure in which the groove structures 21 include only one annular groove 212. In this case, in the periphery of the annular groove 212, that is, in a region away from the light-emitting element 40, the multiple blind holes 211 are also provided to facilitate the filling of the light-shielding layer 30, thereby enabling the blind holes 211 and the annular groove 212 to cooperate to fill the light-shielding layer 30. Additionally, FIG. 17 illustrates the structure in which the groove structures 21 include two annular grooves 212. The light-shielding layer 30 is filled through the multiple annular grooves 212.

It is to be noted that the orthographic projection of the annular groove 212 on the base substrate 10 surrounds the orthographic projection of the light-emitting element 40 on the base substrate 10. That is, the annular groove 212 is provided around the periphery of the light-emitting element 40, that is, surrounds the light-emitting element 40. Additionally, there is a certain distance from the annular groove 212 to the light-emitting element 40. The provision of the annular groove 212 can accommodate more of the semi-fluid light-shielding layer 30 near the light-emitting element 40, thereby lowering the fluid level of the light-shielding layer 30. This can prevent the fluid level of the light-shielding layer 30 from becoming high and thereby prevent the light-shielding layer 30 from creeping onto the light-emitting element 40, thereby improving the light-emitting brightness of the light-emitting element 40. Additionally, the annular groove 212 surrounds the light-emitting element 40 so that the annular groove 212 can uniformly accommodate the light-shielding layer 30 around all sides of the light-emitting element 40, thereby preventing local regions around the light-emitting element 40 from having relatively high fluid levels. This can effectively inhibit the light-shielding layer 30 from creeping onto the light-emitting element 40, thereby improving the light-emitting brightness of the light-emitting element 40.

It is also to be noted that, referring to FIG. 18, in the direction perpendicular to the base substrate 10, the depth of the annular groove 212 is smaller than the thickness of the insulating layer 20, that is, the thickness of the insulating layer 20 is larger than the depth of the annular groove 212, that is, the depth of the annular groove 212 does not reach the bottom end on the other side of the insulating layer 20. An opening of the annular groove 212 is directed towards the side of the insulating layer 20 facing away from the base substrate 10. Such a configuration can ensure that, when the light-shielding layer 30 is inkjet-printed, the annular groove 212 can accommodate the semi-fluid light-shielding layer 30 in the region near the light-emitting element 40, effectively lowering the fluid level of the light-shielding layer 30 near the light-emitting element 40, lowering the probability of the light-shielding layer 30 creeping onto the sidewall of the light-emitting element 40, and ensuring the light-emitting efficiency of the light-emitting element 40 and the display effect of the display panel.

Additionally, the size of the annular groove 212 is also configurable. That is, when the groove structures 21 include at least two annular grooves 212, the annular grooves 212 may be arranged in at least two concentric circles surrounding the light-emitting element 40. Referring to FIG. 17, in this case, the size of an annular groove 212 in the outer circle may be larger than the size of an annular groove 212 in the inner circle, or the size of the annular groove 212 in the inner circle may be larger than the size of the annular groove 212 in the outer circle. Certainly, the size of the annular groove 212 in the inner circle 212 may be equal to the size of the annular groove 212 in the outer circle. Under the premise that the annular grooves 212 are configured to accommodate parts of the light-shielding layer 30 to reduce the fluid level of the light-shielding layer 30 around the light-emitting element 40, reducing the probability of the light-shielding layer 30 creeping onto the sidewall of the light-emitting element 40 and ensuring the light-emitting efficiency of the light-emitting element 40 and the display effect of the display panel, the size of the annular groove 212 and the arrangement of the annular grooves 212 are not specifically limited and may be determined based on the actual conditions.

It is to be understood that, with respect to the shape of the annular groove 212, the projection shape of the annular groove 212 on the base substrate 10 may be circular, square, rectangular, triangular, rhombic, semi-circular, semi-elliptical, or another suitable shape, which is not specifically limited in this embodiment under the premise that the core inventive concept of the present disclosure is not affected. For ease of understanding and explanation, the following descriptions of the annular groove 212 are specifically provided based on the example in which the shape of the annular groove 212 is rectangular.

It is also to be understood that, from a cross-sectional view of the annular groove 212, the sidewall of the annular groove 212 may be vertical, inclined inward or outward, or curved, which is not specifically limited in this embodiment under the premise that the core inventive concept of the present disclosure is not affected. To ensure a better accommodation effect, the sidewall of the annular groove 212 may be inclined inward, that is, in the shape of a regular trapezoid. Moreover, if the opening of the annular groove 212 is small, this can reduce the area occupied during the hole-forming process, thereby avoiding an excessive area that affects a routing region for wiring.

In one or more embodiments, with continued reference to FIG. 16, the groove structure 21 further includes the multiple blind holes 211, and the orthographic projections of the multiple blind holes 211 on the base substrate 10 are arranged around the orthographic projection of the annular groove 212 on the base substrate 10.

Specifically, when the groove structures 21 include the multiple blind holes 211 and the annular groove 212, the orthographic projections of the multiple blind holes 211 on the base substrate 10 are arranged around the orthographic projection of the annular groove 212 on the base substrate 10. In other words, the light-emitting element 40 is located within a region enclosed by the annular groove 212, and the annular groove 212 is located within a region enclosed by the multiple blind holes 211. There is a certain distance from the edge of each blind hole 211 to the annular groove 212. The advantage of such a configuration is that, during the inkjet printing of the semi-fluid light-shielding layer 30, the light-shielding layer 30 can preferentially fill the outermost multiple blind holes 211 and then fill the annular groove 212 around the periphery of the light-emitting element 40, and only after the blind holes 211 and the annular groove 212 are filled with the light-shielding layer 30 is the remaining light-shielding layer 30 deposited on the surface of the metal layer 50. As such, with the joint cooperation of the annular groove 212 and the blind holes 211, the light-shielding layer 30 flowing in from all directions can be accommodated within the blind holes 211 and the annular groove 212, thereby lowering the fluid level of the light-shielding layer 30 near the light-emitting element 40, preventing the fluid level of the light-shielding layer 30 from becoming high, and thereby preventing the light-shielding layer 30 from creeping onto the light-emitting element 40 due to the capillary effect caused by the microstructure on the surface of the light-emitting element 40. This can even prevent the light-shielding layer 30 from creeping onto the light-emitting element 40, thereby ensuring the light-emitting efficiency of the light-emitting element 40. Additionally, the formation of the annular groove 212 on one side closest to the light-emitting element 40 can make the light-shielding layer 30 within the annular groove 212 flatter and more uniform, thereby avoiding excessive differences in the shielding height of the sidewall of the light-emitting element 40 and ensuring the light-shielding effect of the light-shielding layer 30. Moreover, the multiple independent blind holes 211 are provided around the periphery of the annular groove 212 to make the overall pattern of the metal layer 50 more uniform. The blind holes 211 formed in the metal layer 50 accommodate the light-shielding layer 30, ensuring a more uniform light-shielding effect of the light-shielding layer 30. It is also to be noted that, on this basis, when the metal layer 50 is provided between the light-shielding layer 30 and the insulating layer 20, the morphology of the metal layer 50 is the same as the morphology of the blind hole 211. That is, if the projection shape of the blind hole 211 is square, an opening at a corresponding position of the metal layer 50 is also square; if the projection shape of the blind hole 211 is circular, the opening at the corresponding position of the metal layer 50 is also circular, which may be determined based on the actual conditions and is not limited herein.

In one or more embodiments, with continued reference to FIGS. 17 and 18, the orthographic projection of the annular groove 212 on the base substrate 10 is rectangular, circular, or elliptical, and/or the orthographic projection of the annular groove 212 on the plane perpendicular to the base substrate 10 is semicircular, semi-elliptical, rectangular, or trapezoidal.

Specifically, the orthographic projection of the annular groove 212 on the base substrate 10 is rectangular, circular, or elliptical, that is, when the annular groove 212 is formed, the projection shape of the annular groove 212 may be circular, elliptical, or rectangular, which may be set based on the actual conditions and is not limited herein under the premise that the annular grooves 212 can accommodate more of the light-shielding layer 30. Additionally, the orthographic projection of the annular groove 212 on the plane perpendicular to the base substrate 10 is semicircular, semi-elliptical, rectangular, or trapezoidal, that is, the sidewall of the annular groove 212 may be arc-shaped, a vertical line, or inclined inward or outward, which may be set based on the actual conditions and is not limited herein under the premise that the annular grooves 212 can accommodate more of the light-shielding layer 30. Referring to FIG. 17, with the formation of the closed annular groove 212, a groove path surrounding the light-emitting element 40 can be formed through annular trenching. As such, when excessive local deposition of the light-shielding layer 30 occurs, another annular groove 212 can be used to divert the light-shielding layer 30 to other regions, thereby ensuring the uniformity of the light-shielding layer 30.

In one or more embodiments, FIG. 19 is another top view of a display panel according to embodiments of the present disclosure. Referring to FIG. 19, the display panel further includes redundant electrode pairs 300, a redundant electrode pair 300 of the redundant electrode pairs 300 includes two redundant electrodes 3001, and the redundant electrodes 3001 are located on the side of the insulating layer 20 facing away from the base substrate 10; the display panel further includes multiple pixel unit regions 400, at least two light-emitting elements 40 and at least one redundant electrode pair 300 are located in the same pixel unit region 400, and at least part of the groove structure 21 is located outside the same pixel unit region 400.

The redundant electrode pair 300 serves as a backup light-emitting structure used when the light-emitting element 40 fails during testing. The redundant electrode pair 300 includes the two redundant electrodes 3001 that may be electrically connected through the second metal portion 502 to enable light emission. The pixel unit region 400 typically refers to a basic light-emitting unit in the display panel that constitutes image display, such as pixels used in an LED display screen, an organic light-emitting diode (OLED) screen, and the like. Each pixel is formed by one or more sub-pixels, which can emit light of different colors (such as red, green, and blue (RGB)). Various colors can be generated by mixing these primary colors. Additionally, the pixel unit region 400 may further include a pixel definition layer to define the specific position of a light-emitting layer in each light-emitting element 40.

Specifically, the at least two light-emitting elements 40 and the at least one redundant electrode pair 300 are located in the same pixel unit region 400, that is, at least two light-emitting elements 40 and at least one redundant electrode pair 300 or three light-emitting elements 40 and three redundant electrode pairs 300 may be provided in a pixel unit 400, which may be determined based on the actual conditions and is not limited herein. After being arranged, the light-emitting elements 40 may be powered to determine the light-emitting effects of the light-emitting elements 40. If any light-emitting element 40 malfunctions, the redundant electrode pair 300 is used to emit light, that is, the light-emitting effect is enabled by powering the redundant electrode pair 300. Additionally, the at least part of the groove structure 21 is located outside the same pixel unit region 400, that is, a part of the groove structure 21 is disposed in a peripheral region of the pixel unit region 400, and a part of the groove structure 21 may also be disposed in the pixel unit region 400 as required. The groove structure 21 accommodates the part of the light-shielding layer 30, thereby lowering the fluid level of the light-shielding layer 30 and increasing the difficulty of the light-shielding layer 30 creeping onto the pixel unit region 400. This ensures the light-emitting efficiency of the light-emitting elements 40 and redundant electrodes 3001 in the pixel unit region 400, thereby enhancing the display effect of the display panel.

In one or more embodiments, with continued reference to FIG. 19, the groove structures 21 include a first sub-groove structure 230 and a second sub-groove structure 240; the first sub-groove structure 230 is located outside the same pixel unit region 400, and the second sub-groove structure 240 is located within the same pixel unit region 400; the orthographic projection of the second sub-groove structure 240 on the base substrate 10 is located between the orthographic projections of adjacent light-emitting elements 40 on the base substrate 10; and/or the orthographic projection of the second sub-groove structure 240 on the base substrate 10 is located between the orthographic projections of adjacent redundant electrodes 3001 on the base substrate 10; and/or the orthographic projection of the second sub-groove structure 240 on the base substrate 10 is located between the orthographic projections of adjacent light-emitting element 40 and redundant electrode 3001 on the base substrate 10.

Specifically, the first sub-groove structure 230 is located outside the pixel unit region 400, and the second sub-groove structure 240 is located within the pixel unit region 400, that is, the first sub-groove structure 230 may be disposed in a region outside the pixel unit region 400 for light emission, and the second sub-groove structure 240 may be disposed within the pixel unit region 400. As such, when the light-shielding layer 30 is formed by inkjet printing, the semi-fluid light-shielding layer 30 preferentially fills the first sub-groove structure 230 and the second sub-groove structure 240 in the periphery, and after the first sub-groove structure 230 and the second sub-groove structure 240 accommodate the part of the light-shielding layer 30, the fluid level of the light-shielding layer 30 around the periphery of the pixel unit region 400 can be greatly lowered, thereby increasing the difficulty of the light-shielding layer 30 creeping onto the sidewall of the pixel unit region 400 and further ensuring the light-emitting efficiency of the pixel unit region 400.

It is to be noted that, with respect to the specific position of the second sub-groove structure 240 located within the pixel unit region 400, in this embodiment, the orthographic projection of the second sub-groove structure 240 disposed on the base substrate 10 is located between the orthographic projections of the adjacent light-emitting elements 40 on the base substrate 10; and/or the orthographic projection of the second sub-groove structure 240 disposed on the base substrate 10 is located between the orthographic projections of the adjacent redundant electrodes 3001 on the base substrate 10; and/or the orthographic projection of the second sub-groove structure 240 disposed on the base substrate 10 is located between the orthographic projections of the adjacent light-emitting element 40 and redundant electrode 3001 on the base substrate 10. In other words, the second sub-groove structure 240 may be disposed between every two adjacent light-emitting elements 40, between every two adjacent redundant electrodes 3001, or between every adjacent light-emitting element 40 and redundant electrode 3001. Referring to the smaller circular groove structure illustrated in FIG. 19, that is, the second sub-groove structure 240, the advantage of such a configuration is that the light-shielding layer 30 can be prevented from being accumulated in the gaps between the adjacent light-emitting elements 40, the adjacent redundant electrodes 3001, and the adjacent light-emitting element 40 and redundant electrode 3001, and the second sub-groove structure 240 can fill part of the light-shielding layer 30 deposited in these gaps, thereby greatly lowering the fluid level of the light-shielding layer 30 in these gaps. This can more effectively resist the adhesion force of the pixel unit region 400, thereby preventing the light-shielding layer 30 from creeping onto the pixel unit region 400, improving the light-emitting efficiency of the pixel unit region 400, and enhancing the display effect of the display panel.

Additionally, whether the second sub-groove structure 240 is disposed according to one of the preceding manners, two of the preceding manners, or all the preceding three manners may be determined based on the actual conditions, and is not limited herein. It can be understood that the larger the number of groove structures 21 is, the more the light-shielding layer 30 is accommodated, and the better the accommodation effect is. Correspondingly, the process becomes more complex, the process difficulty increases, and the efficiency decreases. Therefore, the number of groove structures 21 may be manufactured based on actual requirements.

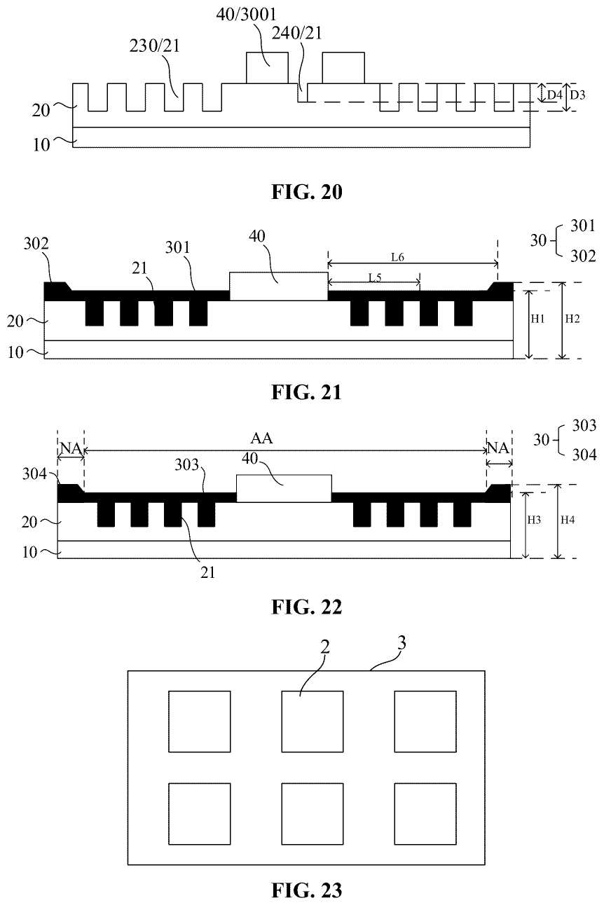

In one or more embodiments, FIG. 20 is a cross-sectional view of the display panel shown in FIG. 19. Referring to FIGS. 19 and 20, the area of the orthographic projection of the first sub-groove structure 230 on the base substrate 10 is S1, and the area of the orthographic projection of the second sub-groove structure 240 on the base substrate 10 is S2; in the direction perpendicular to the base substrate 10, the depth of the first sub-groove structure 230 is D3, and the depth of the second sub-groove structure 240 is D4; S1>S2, and/or D3>D4.

Specifically, referring to FIG. 19, the area of the orthographic projection of the first sub-groove structure 230 on the base substrate 10 is S1, the area of the orthographic projection of the second sub-groove structure 240 on the base substrate 10 is S2, and S1>S2, that is, using the projections of the first sub-groove structure 230 and the second sub-groove structure 240 being circular as an example, the diameter of the circle of the first sub-groove structure 230 is larger than the diameter of the circle of the second sub-groove structure 240. In other words, the first sub-groove structure 230 located outside the pixel unit region 400 is made larger than the second sub-groove structure 240 located within the pixel unit region 400. This is because the region outside the pixel unit region 400 is larger and free of other devices, making the manufacturing process of the first sub-groove structures 230 simpler and more convenient. Therefore, the first sub-groove structures 230 can be made larger to accommodate more of the light-shielding layer 30. For the second sub-groove structure 240 located within the pixel unit region 400, due to the presence of the light-emitting elements 40 and the redundant electrodes 3001, as well as the small distance between the adjacent light-emitting elements 40 and between the adjacent redundant electrodes 3001, if the second sub-groove structure 240 is made to the same size as the first sub-groove structure 230, higher process requirements and greater difficulty arise. Therefore, to facilitate manufacturing, reduce the process difficulty, and improve the manufacturing efficiency, in this embodiment, the size of the second sub-groove structure 240 is smaller than the size of the first sub-groove structure 230. As such, without affecting the function of the first sub-groove structure 230 and the second sub-groove structure 240 in accommodating the light-shielding layer 30, the process difficulty is reduced, the manufacturing is facilitated, and the manufacturing efficiency is improved.

It is to be noted that, referring to FIG. 20, in the direction perpendicular to the base substrate 10, the depth of the first sub-groove structure 230 is D3, the depth of the second sub-groove structure 240 is D4, and D3>D4, that is, when the first sub-groove structure 230 and the second sub-groove structure 240 are manufactured, the depth of the first sub-groove structure 230 is larger than the depth of the second sub-groove structure 240. In other words, the height of the first sub-groove structure 230 located outside the pixel unit region 400 is made greater than the height of the second sub-groove structure 240 located within the pixel unit region 400. This is because the region outside the pixel unit region 400 is larger and free of other devices, making the manufacturing process of the first sub-groove structures 230 simpler and more convenient. Therefore, the first sub-groove structures 230 can be made deeper to accommodate more of the light-shielding layer 30. For the second sub-groove structure 240 located within the pixel unit region 400, due to the presence of the light-emitting elements 40 and the redundant electrodes 3001, as well as the small distance between the adjacent light-emitting elements 40 and between the adjacent redundant electrodes 3001, if the second sub-groove structure 240 is made to the same depth as the first sub-groove structure 230, higher process requirements and greater difficulty arise. Therefore, to facilitate manufacturing, reduce the process difficulty, and improve the manufacturing efficiency, in this embodiment, the depth of the second sub-groove structure 240 is less than the depth of the first sub-groove structure 230. As such, without affecting the function of the first sub-groove structure 230 and the second sub-groove structure 240 in accommodating the light-shielding layer 30, the process difficulty is reduced, the manufacturing is facilitated, and the manufacturing efficiency is improved.

In one or more embodiments, FIG. 21 is another diagram illustrating the structure of a display panel according to embodiments of the present disclosure. Referring to FIG. 21, the light-shielding layer 30 includes a first light-shielding portion 301 and a second light-shielding portion 302; in the direction parallel to the base substrate 10, the distance from the first light-shielding portion 301 to the light-emitting element 40 is L5, and the distance from the second light-shielding portion 302 to the light-emitting element 40 is L6; in the direction perpendicular to the base substrate 10, the minimum distance from the surface of one side of the first light-shielding portion 301 facing away from the base substrate 10 to the base substrate 10 is H1, and the minimum distance from the surface of one side of the second light-shielding portion 302 facing away from the base substrate 10 to the base substrate 10 is H2; L5<L6, and H1<H2.

Specifically, in the direction parallel to the base substrate 10, the distance from the first light-shielding portion 301 to the light-emitting element 40 is L5, the distance from the second light-shielding portion 302 to the light-emitting element 40 is L6, and L5<L6, that is, the first light-shielding portion 301 is closer to the light-emitting element 40 than the second light-shielding portion 302. In other words, the first light-shielding portion 301 is located around the periphery of the light-emitting element 40, while the second light-shielding portion 302 is located around the periphery of the first light-shielding portion 301. Moreover, in the direction perpendicular to the base substrate 10, the minimum distance from the surface of the side of the first light-shielding portion 301 facing away from the base substrate 10 to the base substrate 10 is H1, the minimum distance from the surface of the side of the second light-shielding portion 302 facing away from the base substrate 10 to the base substrate 10 is H2, and H1<H2, that is, the first light-shielding portion 301, which is closer to the light-emitting element 40, is closer to the base substrate 10 than the second light-shielding portion 302, which is farther from the light-emitting element 40. In other words, the first light-shielding portion 301 closer to the light-emitting element 40 is thinner, while the second light-shielding portion 302 farther from the light-emitting element 40 is thicker. That is, in a region closer to the light-emitting element 40, the light-blocking layer 30 is relatively thinner and has a lower fluid level. The advantage of such a configuration is that the difficulty of the light-blocking layer 30 near the light-emitting element 40 creeping onto the light-emitting element 40 is increased, making it less likely for the light-blocking layer 30 to reach the sidewall of the light-emitting element 40. As a result, the probability of the light-blocking layer 30 reaching the light-emitting element 40 is lowered, ensuring that the light-emitting element 40 remains free from foreign object obstruction, improving the light-emitting efficiency of the light-emitting element 40, and enhancing the display effect of the display panel.

In one or more embodiments, FIG. 22 is another diagram illustrating the structure of a display panel according to embodiments of the present disclosure. Referring to FIG. 22, the display panel further includes a display region AA and a non-display region NA, and the light-emitting element 40 is located in the display region AA; the light-shielding layer 30 includes a third light-shielding portion 303 and a fourth light-shielding portion 304, the third light-shielding portion 303 is located in the display region AA, and the fourth light-shielding portion 304 is located in the non-display region NA; in the direction perpendicular to the base substrate 10, the minimum distance from the surface of one side of the third light-shielding portion 303 facing away from the base substrate 10 to the base substrate 10 is H3, and the minimum distance from the surface of one side of the fourth light-shielding portion 304 facing away from the base substrate 10 to the base substrate 10 is H4; H3<H4.

The display region AA refers to a portion of the display panel actually used to present images, videos, or other visual content. The display region AA includes all the pixel points, and various pieces of information are displayed by controlling the brightness and colors of these pixels. The non-display region NA refers to a bezel portion surrounding the periphery of the display region, which is not involved in the direct display of content. In other words, the display region AA is dedicated to providing high-quality visual output, while the non-display region NA is responsible for supporting the technical requirements of the display region AA.

Specifically, the third light-shielding portion 303 is disposed in the display region AA, and the fourth light-shielding portion 304 is disposed in the non-display region NA; in the direction perpendicular to the base substrate 10, the minimum distance from the surface of the side of the third light-shielding portion 303 facing away from the base substrate 10 to the base substrate 10 is H3, and the minimum distance from the surface of the side of the fourth light-shielding portion 304 facing away from the base substrate 10 to the base substrate 10 is H4; H3<H4, that is, the third light-shielding portion 303 located in the display region AA is closer to the base substrate 10 than the fourth light-shielding portion 304 located in the non-display region NA. In other words, the third light-shielding portion 303 in the display region AA is thinner, while the fourth light-shielding portion 304 in the non-display region NA is thicker. That is, the light-blocking layer 30 located in the display region AA is relatively thin, and the fluid level of the light-blocking layer 30 located in the display region AA is lower than the fluid level of the fourth light-shielding portion 304 in the non-display region NA. The advantage of such a configuration is that the difficulty of the light-blocking layer 30 near the light-emitting element 40 creeping onto the light-emitting element 40 is increased, making it less likely for the light-blocking layer 30 to reach the sidewall of the light-emitting element 40. As a result, the probability of the light-blocking layer 30 reaching the light-emitting element 40 is lowered, ensuring that the light-emitting element 40 remains free from foreign object obstruction, improving the light-emitting efficiency of the light-emitting element 40, and enhancing the display effect of the display panel.

Based on the same inventive concept, the embodiments of the present disclosure further provide a display device. FIG. 23 is a diagram illustrating the structure of a display device according to embodiments of the present disclosure. As shown in FIG. 23, the display device 3 includes the display panel 2 according to any embodiment of the present disclosure. Therefore, the display device 3 provided in the embodiments of the present disclosure has the technical effects of the technical solution of any one of the preceding embodiments, and structures that are the same as or correspond to the structures in the preceding embodiments and the explanation of the terms are not repeated herein. The display device 3 provided in the embodiments of the present disclosure may be a mobile phone as shown in FIG. 23, or may be any electronic product having a display function, including, but not limited to, an electronic billboard in a shopping mall, a stadium display screen, a concert display screen, or another electronic product, which is not limited in the embodiments of the present disclosure.

It is to be noted that the preceding are preferred embodiments of the present disclosure and technical principles used therein. It is to be understood by those skilled in the art that the present disclosure is not limited to the embodiments described herein. Those skilled in the art can make various apparent modifications, adaptations, combinations, and substitutions without departing from the scope of the present disclosure. Therefore, while the present disclosure is described in detail through the preceding embodiments, the present disclosure is not limited to the preceding embodiments and may include other equivalent embodiments without departing from the concept of the present disclosure. The scope of the present disclosure is determined by the scope of the appended claims.

What is claimed is:

1. A display panel, comprising:
a base substrate;
an insulating layer located on a surface of the base substrate, wherein a surface of one side of the insulating layer facing away from the base substrate is provided with groove structures; and
a light-shielding layer and a light-emitting element that are located on the side of the insulating layer facing away from the base substrate, wherein an orthographic projection of the light-shielding layer on the base substrate is at least located around an orthographic projection of the light-emitting element on the base substrate, and at least part of the light-shielding layer is located within the groove structures.

2. The display panel according to claim 1, further comprising a metal layer located between the insulating layer and the light-shielding layer,
wherein the metal layer comprises a first metal portion, the first metal portion has a first opening and second openings, the orthographic projection of the light-emitting element on the base substrate is located within an orthographic projection of the first opening on the base substrate, and orthographic projections of the second openings on the base substrate at least partially overlap orthographic projections of the groove structures on the base substrate.

3. The display panel according to claim 2, wherein the metal layer further comprises a second metal portion located within the first opening;
the display panel further comprises a circuit function layer located between the base substrate and the insulating layer; and
the circuit function layer comprises a pixel circuit, the pixel circuit is electrically connected to the second metal portion, and the second metal portion is electrically connected to the light-emitting element.

4. The display panel according to claim 2, wherein the orthographic projections of the second openings on the base substrate coincide with the orthographic projections of the groove structures on the base substrate.

5. The display panel according to claim 2, wherein the orthographic projections of the groove structures on the base substrate are located within the orthographic projections of the second opening on the base substrate; geometric centers of orthographic projections of at least some of the groove structures on the base substrate do not coincide with geometric centers of the orthographic projections of corresponding second openings on the base substrate.

6. The display panel according to claim 2, wherein the orthographic projections of the groove structures on the base substrate partially overlap the orthographic projections of the second openings on the base substrate, and at least part of the metal layer is located within the groove structures.

7. The display panel according to claim 1, wherein the groove structures comprise a plurality of blind holes, and in a direction perpendicular to the base substrate, a depth of a blind hole of the plurality of blind holes is smaller than a thickness of the insulating layer.

8. The display panel according to claim 7, wherein orthographic projections of the plurality of blind holes on the base substrate are arranged around the orthographic projection of the light-emitting element on the base substrate.

9. The display panel according to claim 7, wherein the plurality of blind holes at least form a first blind hole group and a second blind hole group; and
orthographic projections of blind holes in the first blind hole group on the base substrate are arranged around the orthographic projection of the light-emitting element on the base substrate, and orthographic projections of blind holes in the second blind hole group on the base substrate are arranged around an orthographic projection of the first blind hole group on the base substrate.

10. The display panel according to claim 9, wherein the first blind hole group comprises adjacent first blind hole and second blind hole, a line connecting a center of the first blind hole and a center of the second blind hole is a first connection line, a direction perpendicular to the first connection line is a first direction, and along the first direction, a center of at least one blind hole in the second blind hole group is located between the first blind hole and the second blind hole, or
wherein a diameter of a blind hole in the first blind hole group is smaller than a diameter of a blind hole in the second blind hole group.

11. The display panel according to claim 7, wherein
the plurality of blind holes comprise a first blind hole and a second blind hole; and
in a direction parallel to the base substrate, a distance from the first blind hole to the light-emitting element is larger than a distance from the second blind hole to the light-emitting element, and a diameter of the first blind hole is larger than a diameter of the second blind hole, or
wherein the plurality of blind holes comprise a first blind hole and a second blind hole;
in a direction parallel to the base substrate, a distance from the first blind hole to the light-emitting element is L1, and a distance from the second blind hole to the light-emitting element is L2; and
in the direction perpendicular to the base substrate, a depth of the first blind hole is D1, and a depth of the second blind hole is D2,
wherein L1<L2; D1<D2, or D1>D2.

12. The display panel according to claim 7, wherein the plurality of blind holes comprise a first blind hole, a second blind hole, a third blind hole, and a fourth blind hole;
the first blind hole is adjacent to the second blind hole, and the third blind hole is adjacent to the fourth blind hole; and
in a direction parallel to the base substrate, a distance from one of the first blind hole or the second blind hole that is closest to the light-emitting element to the light-emitting element is L1, a distance from one of the third blind hole or the fourth blind hole that is closest to the light-emitting element to the light-emitting element is L2, a distance from the first blind hole to the second blind hole is L3, and a distance from the third blind hole to the fourth blind hole is L4, wherein L1<L2; L3<L4, or L3>L4.

13. The display panel according to claim 7, wherein an orthographic projection of the blind hole on the base substrate is circular, elliptical, or polygonal, and/or an orthographic projection of the blind hole on a plane perpendicular to the base substrate is semicircular, semi-elliptical, rectangular, or trapezoidal.

14. The display panel according to claim 1, wherein the groove structures comprise at least one annular groove, an orthographic projection of an annular groove of the at least one annular groove on the base substrate surrounds the orthographic projection of the light-emitting element on the base substrate, and in a direction perpendicular to the base substrate, a depth of the annular groove is smaller than a thickness of the insulating layer.

15. The display panel according to claim 14, wherein the groove structures further comprise a plurality of blind holes, and orthographic projections of the plurality of blind holes on the base substrate are arranged around the orthographic projection of the annular groove on the base substrate.

16. The display panel according to claim 1, further comprising a redundant electrode pair,
wherein the redundant electrode pair comprises two redundant electrodes, and the two redundant electrodes are located on the side of the insulating layer facing away from the base substrate; and
wherein the display panel further comprises a plurality of pixel unit regions, at least two light-emitting elements and at least one redundant electrode pair are located in a same pixel unit region of the plurality of pixel unit regions, and at least part of the groove structures are located outside the same pixel unit region.

17. The display panel according to claim 16, wherein the groove structures comprise a first sub-groove structure and a second sub-groove structure;
the first sub-groove structure is located outside the same pixel unit region, and the second sub-groove structure is located within the same pixel unit region; and
an orthographic projection of the second sub-groove structure on the base substrate is located between orthographic projections of adjacent light-emitting elements on the base substrate; and/or the orthographic projection of the second sub-groove structure on the base substrate is located between orthographic projections of adjacent redundant electrodes on the base substrate; and/or the orthographic projection of the second sub-groove structure on the base substrate is located between orthographic projections of adjacent light-emitting element and redundant electrode on the base substrate, or
wherein an area of an orthographic projection of the first sub-groove structure on the base substrate is S1, and an area of the orthographic projection of the second sub-groove structure on the base substrate is S2; in a direction perpendicular to the base substrate, a depth of the first sub-groove structure is D3, and a depth of the second sub-groove structure is D4,
wherein S1>S2, and/or D3>D4.

18. The display panel according to claim 1, wherein the light-shielding layer comprises a first light-shielding portion and a second light-shielding portion;
in a direction parallel to the base substrate, a distance from the first light-shielding portion to the light-emitting element is L5, and a distance from the second light-shielding portion to the light-emitting element is L6; and
in a direction perpendicular to the base substrate, a minimum distance from a surface of one side of the first light-shielding portion facing away from the base substrate to the base substrate is H1, and a minimum distance from a surface of one side of the second light-shielding portion facing away from the base substrate to the base substrate is H2,
wherein L5<L6, and H1<H2.

19. The display panel according to claim 1, further comprising a display region and a non-display region,
wherein the light-emitting element is located in the display region;
wherein the light-shielding layer comprises a third light-shielding portion and a fourth light-shielding portion, the third light-shielding portion is located in the display region, and the fourth light-shielding portion is located in the non-display region;
wherein in a direction perpendicular to the base substrate, a minimum distance from a surface of one side of the third light-shielding portion facing away from the base substrate to the base substrate is H3, and a minimum distance from a surface of one side of the fourth light-shielding portion facing away from the base substrate to the base substrate is H4; and
wherein H3<H4.

20. A display device, comprising a display panel,
wherein the display panel comprises:
a base substrate;
an insulating layer located on one side of the base substrate in a thickness direction, wherein a surface of one side of the insulating layer facing away from the base substrate is provided with groove structures; and
a light-shielding layer and a light-emitting element that are located on the side of the insulating layer facing away from the base substrate, wherein an orthographic projection of the light-shielding layer on the base substrate is at least located around an orthographic projection of the light-emitting element on the base substrate, and at least part of the light-shielding layer is located within the groove structures.
